(19) United States
(12) Patent Application Publication
(10) Pub. No.: US 2013/0327386 A1
(43) Pub. Date: Dec. 12, 2013

(54) THREE-DIMENSIONAL PHOTOVOLTAIC DEVICE

(71) Applicant: Tao Xu, Lisle, IL (US)

(72) Inventor: Tao Xu, Lisle, IL (US)

(21) Appl. No.: 13/493,830

(22) Filed: Jun. 11, 2012

(51) Int. Cl. H01L 31/0236

(52) U.S. Cl. 136/256

(57) ABSTRACT

A photovoltaic device, comprises (1) a transparent first conductive layer, (2) a semiconductor layer on and in contact with the first conductive layer, (3) an electrolyte or p-type semiconductor on the semiconductor layer, and (4) a second conductive layer on the electrolyte or p-type semiconductor. The semiconductor layer has a thickness of at most 100 nm, the first conductive layer has a surface roughness factor (SRF) of at least 10, and the semiconductor layer has a surface roughness factor (SRF) of at least 10

### FEDERALLY SPONSORED RESEARCH OR DEVELOPMENT

This invention was made with government support under CBET-1150617 awarded by the National Science Foundation. The government has certain rights in the invention.

### BACKGROUND

Photovoltaic (PV) systems are systems that convert light into electricity. All photovoltaic systems share a few common parts. All photovoltaic systems include a light-harvesting element, a charge-separating element, a charge-transporting element, and a charge collecting element.

Dye-sensitized solar cells (DSSCs) are an important class of photovoltaic systems, and provide a model for other photovoltaic systems. A typical DSSC (for example, as described in Jeong, J-A and Kim, H-K, Solar energy Materials & Solar Cells, 95 (2011) 344-348) includes a dye in combination with a surface of titanium oxide (TiO₂), which acts as the light-harvesting element, by absorbing light to create an electron-hole pair. The titanium oxide is often present as nanoparticles to form a nanoporous layer, in order to maximize the surface area onto which the dye is absorbed, to maximize the amount of dye available to absorb incoming light. The nanoporous titanium oxide functions as the charge-separating element: the conduction band of the titanium oxide has empty energy levels available to receive electrons from the electron-hole pairs created by the absorption of light, which have an energy similar to, but less than, the energy of the photoelectrons. The holes remain with the dye molecules, creating a dye cation (dye⁺), which is reduced by accepting an electron from a redox mediator present in an electrolye; typically iodide/triiodide (I⁻/I₃⁻) dissolved in a polar solvent is used as the redox mediator. Then, the nanoporous titanium oxide functions as the charge-transporting element, moving the electron away from the dye-TiO₂ interface, to a collecting transparent conducting electrode (such as fluorinated tin oxide, or indium tin oxide) on a glass substrate. To complete the electrical circuit, the redox mediator accepts an electron from a platinum layer on a counter electrode (also called cathode or back electrode). Also present is a passivating layer of TiO₂ on the transparent conducting tin oxide, which reduces the incidence of electrons which have been collected from being lost due to reaction which the redox mediator.

A challenge in many photovoltaic systems is the fundamentally conflicting demands on the thickness of the photovoltaic layer. The photovoltaic layer must be thick enough to accommodate the incident solar flux and create adequate light-induced electron-hole pairs. However, a thick photovoltaic layer increases the length of charge transport pathways, where a high risk of recombination is present. More photovoltaic materials also increase the cost of the photovoltaic device. In contrast, a thinner photovoltaic layer makes the device more affordable and reduces the likelihood of charge recombination. But, a thinner photovoltaic layer deteriorates the light harvesting. This trade-off between light harvesting and charge transporting impedes further development of many photovoltaic systems. For example, in conventional DSSCs, a thick photovoltaic layer, typically greater than 10 μm (for example, a dye-sensitized TiO₂ nanoparticulate film) is necessary for adequate light harvesting efficiency. However, the long transport distances inevitable result in slow electron transport to the collecting electrode. This imposes addition constrains on the photovoltaic device.

For DSSCs with a TiO₂ nanoparticle-based photoanode soaked in liquid iodide electrolyte, the photoelectrons strongly couple with the counter-ions (for example, Li⁺ from Lil dissolved in the electrolyte). Thus, there is no macroscopic drift transport in the TiO₂ nanoparticle network. Rather, the electron transport in most of the wet and illuminated TiO₂ nanoparticle network occurs via trap-limited ambipolar diffusion. The kinetics can be estimated as T_{d}=dₑ²/D₀, where T_{d} is the time for an electron diffusing across a distance of dₑ in the TiO₂ nanoparticle layer, and D₀ is the electron diffusivity. On average, in a 15-μm-thick TiO₂ nanoparticle film, a moving electron encounters one million trapping/detrapping events at the defect sites and takes milliseconds to seconds to percolate through the TiO₂ nanoparticle film prior to reaching the transparent conducting electrode.

Such slow electron transport leads to a major compromise between photocurrent and photovoltage in current DSSCs. Specifically, slow redox shuttles are desirable to avoid recombination to attain high photocurrent, while fast shuttles are desirable to reduce (regenerate) the dye cations promptly. As a compromise, an over-potential of slow redox shuttles is necessary for efficient regeneration of dyes at a significant loss in open-circuit voltage (V_{oc}), about 0.6 V for I⁻/I₃⁻ redox mediator.

There also exists a conflict between light harvesting efficiency (LHE) and charge collection efficiency (CCE). A conventional DSSC requires a surface roughness factor (SRF) of greater than 1000 to load enough dye to achieve a nearly 100% LHE at peak absorption of the dyes. This SRF is equivalent to about a 15 μm thick TiO₂ nanoparticle layer (assuming each nanoparticle is about 20 nm in diameter). However, a thicker photovoltaic layer also leads to increased charge recombination due to elongation of the charge transport distance in the photovoltaic layer, and consequently lowers the CCE. In the simplest linear model, CCE in a TiO₂ nanoparticle-based DSSC can be estimated as CCE=1−T_{d}/tₙ. Here, Tₙ is the electron recombination time, which is mainly associated with the kinetics and energetics of the redox shuttles. Tₙ, however, depends on the electron transport distance (dₑ) and the electron diffusivity (D₀) in the TiO₂ nanoparticle network. Various defects in the TiO₂ nanoparticle network are inevitably present and can trap electrons, hence significantly decrease D₀. Thus, only a handful of research groups have reported DSSCs with overall device efficiency exceeding 10%. In these reports, deliberate optimization of the quality of the TiO₂ nanoparticle layer was critical for achieving high electron diffusion coefficient (D₀>10⁻⁵ m) to realize a CCE as high as 90%. Nonetheless, the best optimized DSSCs still require sacrificing the attainable photovoltage through overpotential in redox shuttles, and the redox mediator I⁻/I₃⁻ still outperforms other redox mediators.

Alternatively, 1-dimensional nanostructured photoanodes exhibit faster collection kinetics due to the directed electron pathways and better crystallinity. However, their overall efficiency has not matched that of optimized TiO₂ nanoparticle-based DSSCs, because the conflict between LHE and CCE still exists due to the loss of SRF in 1-dimensional nanowires. Furthermore, longer nanowires must be accommodated by using a thicker electrolyte layer, which can cause constraints in mass flow of redox mediators.

### SUMMARY

In a first aspect, the present invention is a photovoltaic device, comprising (1) a transparent first conductive layer, (2) a semiconductor layer, on and in contact with the first transparent conductive layer, (3) an electrolyte or p-type semiconductor, on the semiconductor layer, and (4) a second conductive layer, on the electrolyte or p-type semiconductor. The semiconductor layer has a thickness of at most 100 nm, the first conductive layer has a surface roughness factor (SRF) of at least 10, and the semiconductor layer has a surface roughness factor (SRF) of at least 10.

In a second aspect, the present invention is a photovoltaic device, comprising (1) a 3-dimentional nanostructured transparent first conductive layer, such as a nanoparticulate transparent conducting layer that has a surface roughness factor (SRF) of at least 10, (2) a first semiconductor layer, comformally on and in contact with the first conductive layer, (3) a blocking layer with a different band energy, conformally on and in contact with the first n-type semiconductor layer (4) an electrolyte or p-type semiconductor, on the second n-type semiconductor layer or blocking layer, (5) a second conductive layer, on the electrolyte or p-type semiconductor, (6) a chromophore, on the first semiconductor layer or blocking layer. The semiconductor layer has a thickness of at most 100 nm, the first conductive layer has a surface roughness factor (SRF) of at least 10, and the semiconductor layer has a surface roughness factor (SRF) of at least 10.

In a third aspect, the present invention is a photovoltaic device, comprising (1) a transparent first conductive layer with light trapping morphology such as an inverse opal structure, (2) a semiconductor layer, conformally on and in contact with the first conductive layer and following its morphology, (3) an electrolyte or p-type semiconductor, on the semiconductor layer, (4) a second conductive layer, conformally on the electrolyte or p-type semiconductor, and (5) a chromophore, on the semiconductor layer. The semiconductor layer has a thickness of at most 30 nm, the first conductive layer has a surface roughness factor (SRF) of at least 10, and the semiconductor layer has a surface roughness factor (SRF) of at least 10.

### DEFINITIONS

Surface roughness factor (SRF) is the surface area divided by the projected substrate area. The surface area is determined by measuring the BET surface area.

A chromophore is a colored material, such as a dye or pigment. A dye forms a chemical bond to a surface. A pigment is a colored material which is not a dye.

### BRIEF DESCRIPTION OF THE DRAWINGS

FIG. 1. (A) Illustration of a photovoltaic device and system. (B) Illustration of an enlarged portion of FIG. 1A showing details at the interface of the first conductive layer and the semiconductor layer.

FIG. 2. The schematic design for fabricating TiO₂ coated TCO network-based photoanode architecture. Note that the TCO NPs are sintered to be interconnected prior to ALD.

FIG. 3. X-ray diffraction pattern (Cu radiation) of FTO nanoparticles sintered at 600° C.

FIG. 4. XPS spectra of FTO nanoparticles. (a) XPS spectra of the wide scan of FTO nanoparticles, (b) high resolution XPS spectra for Sn 3d (c) high resolution XPS spectra for F 1s.

FIG. 5. Typical STEM images of the synthesized FTO nanoparticle coated with 20 nm TiO₂ by ALD method. (a) Low magnification image; (b) close investigation showing the size of the particle and the coating of TiO₂. (c) HAADF-STEM image of the connected FTO particles and the corresponding (d) EELS and line scan profile confirm the Ti residing predominantly in the shell and Sn in the core. All films were first sintered to 500° C. prior to surface treatment. To aid the reader, some regions of the TiO₂ shells are indicated.

FIG. 6. Typical J-V curves of DSSCs based on FTO NPs and SnO₂ NPs under AM 1.5 G illumination. The area of both devices is 0.25 cm².

FIG. 7. The scheme of energy diagram at the interface between FTO and TiO₂ in contact with electrolyte based on I⁻/I₃⁻.

FIG. 8. Nyquist plots of representative EIS data at 450 mV and 550 mV forward bias in the dark condition (a) for FTO-based DSSC (red circle) and SnO₂-based DSSC (blue triangle) and their magnified part at high frequency (b). (c) the equivalent circuit used for fitting data from EIS measurement.

FIG. 9. Characteristic cell data with a dependence on the internal voltage extracted from the EIS spectra (a) The electron transport resistance Rₜᵣ, (b) chemical capacitance C_{μ}, (c) The interfacial charge recombination resistance R_{ct}.

FIG. 10. (a) The calculated electron life time (b) the calculated the effective diffusion length Lₙ, (c) The electron mobility μ versus applied potential, (d) μ versus Cμ in FTO (core)-TiO₂ (shell) DSSC compared to a conventional nanoparticle SnO₂ DSSC.

FIG. 11. Schematic view of the proposed 3-D photonic crystal TCO electrode. The 3-D inverse opal FTO structure can be fabricated using polystyrene beads as template to serve as charge transport and collection material. Then, a thin layer of wide bandgap semiconductor such as TiO₂ can be conformally coated on all surface of the TCO by atomic layer deposition (ALD) method.

FIG. 12. Typical FE-SEM images of synthesized inverse opal FTO (IO-FTO) electrodes. (a) A large topview image of a typical 3D IO-FTO structure. (b) A topview SEM image at high magnification. The top surface is composed of a closely packed, hexagonally-ordered microporous FTO. (c) Cross section view of a fractured IO-FTO film to show the internal pores within the film. (d) Cross section view of a fractured IO-FTO film on the FTO glass to show the thickness of the resulting electrode.

FIG. 13. Typical TEM images of the synthesized IO-FTO electrode coated with 10 nm TiO₂ by ALD method. (a) Low magnification image showing the inverse opal structure; (b) close investigation from the broken part of the thin film showing the thickness of the wall pore. (c) HR-TEM shows the magnified image of the portion defined by the white dashed line in b.

FIG. 14. (a) HAADF-STEM image of one part of the IO wall and the corresponding (b) EELS and line scan profile confirm the Ti residing predominantly in the shell and Sn in the core. The right end from scan line in (a) is defined to be zero on the x-axis in (b). (c) XRD spectra of the 3-D inverse opal FTO film prepared on a regular glass substrate and the calcination temperature for this sample is at 500° C.

FIG. 15. Photocurrent-Voltage characteristics of solar cells using IO-FTO (core)-TiO₂ (shell) as the photoanode. The incident light intensity is 100 mW/cm² and the illumination area is 0.25 cm² for all the samples.

FIG. 16. Nyquist Plots of representative EIS data obtained in the dark condition (a) for bias voltage −0.5V (solid square), −0.6V (solid circle), −0.7V (solid triangle) and their magnified part at high frequency in (b). (c) The equivalent circuit used for fitting data from EIS measurement.

FIG. 17. Fitting results of electron transport resistance Rₜᵣ (a), interfacial charge transfer resistance R_{ct} (b), and chemical potential Cμ (c) for devices based on our IO-FTO (core)-TiO₂ (shell) DSSC (solid triangle) and a nanoparticle TiO₂ DSSC (solid circle) in the dark.

FIG. 18. Derived parameters of electron conductivity (a) and effective diffusion length (b) in a completed IO-FTO (core)-TiO₂ (shell) DSSC compared to a conventional nanoparticle TiO₂ DSSC.

### DETAILED DESCRIPTION

The present invention makes use of the discovery of a new type of photovoltaic device, which separates the components which are involved in light-harvesting, charge-separating and charge-transporting. The photovoltaic device and system of the present invention uses a thin semiconducting layer on a conductive surface, which has a space charge layer to efficiently sweep electrons to the conductive surface, as the charge-separating component. Furthermore, the photovoltaic device and system of the present invention uses the conducting surface as the charge-transporting component, to efficiently transport the electrons. By replacing a thick, often structurally irregular, semiconducting layer for both charge-separating and charge-transporting functions, the present invention provides a much more efficient photovoltaic device and system. However, a thin semiconductor layer would normally result in a low surface roughness factor, reducing the absorption of light by the photovoltaic device. The present invention addresses this problem by using a first conductive layer with a high surface roughness factor; when a thin conformal semiconductor layer is formed on the first conductive layer, the semiconductor layer will also have a high surface roughness factor.

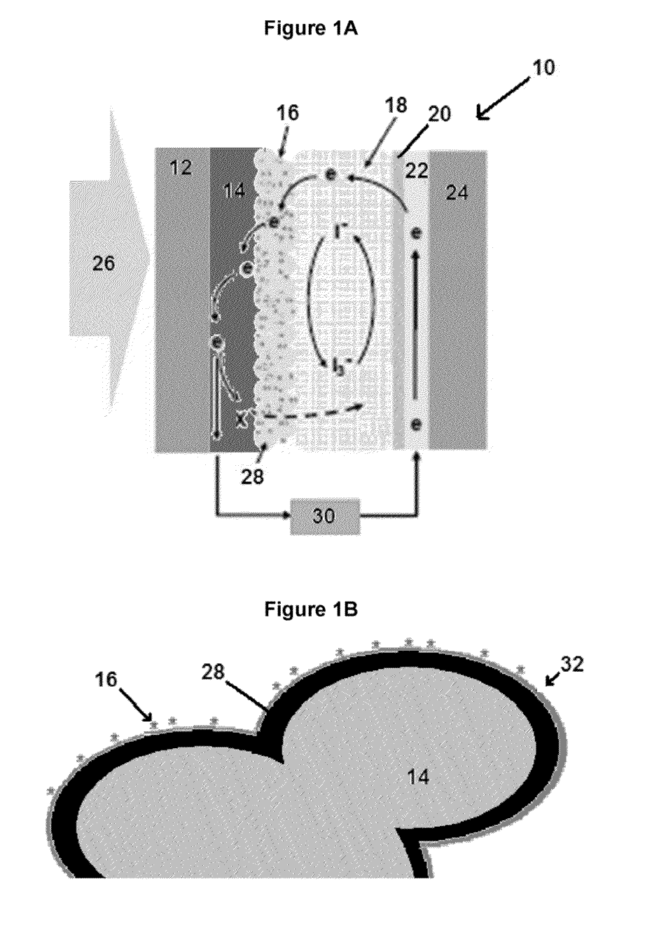

FIG. 1A illustrates a photovoltaic device of the present invention, where the components are not shown to scale. The photovoltaic device, 10, includes an optional substrate, 12, and a first conductive layer, 14, on the substrate. On the conductive layer is a semiconductor layer, 28; optionally a colored light harvesting material, 16, may be on the semiconductor layer. Next, an electrolyte, 18, (containing a redox mediator, shown here as I⁻/I₃⁻) is on the semiconductor layer and on an electrode, 20. The electrolyte may also be replaced with a solid p-type semiconductor. The electrode may be on a second conductive layer, 22, which is itself optionally on an optional support, 24; optionally, the electrode and second conductive layer may be combined into a single layer, referred to as the second conductive layer.

FIG. 1B, also not to scale, illustrates an enlarged portion of FIG. 1A, showing details at the interface of the first conductive layer, 14, and the semiconductor layer, 28. As shown, the semiconductor layer, 28, is on the first conductive layer, 14. On the semiconductor layer is optional colored light harvesting material, 16, such as a dye. Also shown in the figure is an optional blocking layer, 32, on the semiconductor layer. Although shown as a continuous layer on the semiconductor layer, the blocking layer may also be present as island on the semiconductor layer.

A photovoltaic system of the present invention includes the photovoltaic device, 10, along with a load, 30, electrically connected to the photovoltaic device, which connects the first conductive layer and the second conductive layer, completing the electrical circuit. In operation, light, 26, illuminates the semiconductor layer and the optional colored light harvesting material, 16, producing electron-hole pairs. The electrons are swept toward the first conductive layer, by the electric field of the space charge layer present in the semiconductor layer, and are thereby separated from the holes. The electrons are then transported by the first conductive layer. The holes accept an electron from the redox mediator present in the electrolyte, and the redox mediator accepts an electron from the electrode. The circuit is completed by the electron traveling through the load and into the second conductive layer. As illustrated in FIG. 1A, an electron may be lost to the redox mediator present in the electrolyte before it has an opportunity to carry out useful work (represented by the letter “x” and the dotted arrow).

Preferably, the substrate and the first conductive layer are transparent, so that light may penetrate one side of the device and reach the semiconductor layer. Examples of substrates include glass, quartz and transparent polymeric materials, such as polycarbonate. Examples of transparent conductive layers include indium-tin oxide, fluorinated tin oxide, and aluminum-zinc oxide. The first conductive layer may also be formed as a composite material and/or formed as multiple layers. For example, a planar substrate of glass may be coated with a layer of fluorinated tin oxide, and fine particles of fluorinated tin oxide applied to the surface and sintered together to provide the substrate and first conductive layer. This is particularly useful to provide a high surface roughness factor for the first conductive layer.

In an alternative configuration, such as that described in Patent Application Publication, Pub. No. US 2011/0220192, the first conductive layer, with the semiconductor layer and optional colored light harvesting material, are on the support, but spaced away from the electrode and second conducting layer, and not in direct electrical contact therewith. In operation of this alternative configuration, light does not need to travel through the first conductive layer, so a non-transparent conductive layer may be used, for example a metal such as gold or platinum, or a conductive oxide, such as electrically conductive titanium suboxides.

The semiconductor layer, which is n-doped or n-type, may be a transparent semiconductor, such as titanium dioxide (TiO₂), zinc oxide (ZnO), zirconium oxide (ZrO₂), tungsten oxide (WO₃), molybdenum oxide (MoO₃), lead oxide (PbO) or mixtures thereof, especially when forming a dye-sensitized solar cell. For photovoltaic devices which are not dye-sensitized solar cells, the semiconductor layer absorbs light, and may be formed from Si (such as ultrathin amorphous silicon, or ut-Si), CdTe, copper indium gallium selenide (CIGS), copper zinc tin sulfide/selenide (CZTS), or mixtures or composites thereof. Conductive polymers, such as those listed below, may also be used, if they are n-doped, by chemical or electrochemical reduction. Preferably, the semiconductor layer has a thickness of at most 100 nm, for example 1 to 100 nm, including 5, 10, 15, 20, 25, 30, 35, 40, 45, 50, 55, 60, 65, 70, 75, 80, 85, 90 and 95 nm. At the interface of the first conductive layer and the semiconductor layer, a space charge layer is formed, creating an electric field which extends from the interface into the semiconductor layer. The space charge layer is expected to extend about 30 nm from the interface. If the thickness of the semiconductor layer becomes too thick, then the space charge layer will not provide the benefit of sweeping electrons toward the interface and into the first conductive layer. If the semiconductor layer is not intrinsically formed as an n-type semiconductor, such as is the case with TiO₂, is may be chemically n-doped.

The semiconductor layer may be formed by physical vapor deposition, such as evaporation or sputtering, or by chemical deposition, such as atomic layer deposition, or by forming a thin layer of a precursor which is then decomposed to form the semiconductor layer. Electrochemical deposition or deposition from solution, may also be used in the case of conductive polymers. The thickness may be controlled by the amount of semiconductor initially deposited, or by removing deposited semiconductor by etching, such as chemical etching. The semiconductor layer may also be formed by applying a dispersion of fine particles of the semiconductor dispersed into a fluid, for example particles have an average diameter of 5 to 100 nm, including 10, 20, 30, 40, 50, 60, 70, 80 or 90 nm, dispersed in water, or an organic solvent for example alcohols such as methanol or ethanol, or mixtures thereof. Sintering may be desirable to remove the solvent and/or improve the contact between the semiconductor layer and the first conductive layer, or to improve the crystallinity of the semiconductor layer. It is important that the semiconductor layer both conformal and compact. Ideally, the contact between the first conductive layer and the semiconductor layer should be an ohmic contact.

Atomic layer deposition may be carried out by chemical reaction of two compounds which react to form the semiconductor layer. The structure onto which the semiconductor layer is to be deposited is exposed to vapors of the first of the two chemicals, and then exposed to the vapors or gasses of the second of the two chemicals. If necessary, the exposure and/or reaction may be carried out at elevated temperatures. In some instances, byproducts of the reaction may need to be removed before repeating the process, by washing, evacuation, or by the passage of an inert gas over the structure. The process may be repeated until the desired thickness of the semiconductor layer is formed. For example, in the case of the transparent oxide semiconductors, which are typically compounds of a metal and oxygen, the first chemical may be a halide, such as a chloride, bromide or iodide, an oxychloride, oxybromide or oxyiodide, organometallic compounds, alkoxides of the metal and other ceramic precursor compounds (such as titanium isopropoxide), as well as mixtures thereof. The second chemical may be water (H₂O), oxygen (O₂ and/or O₃) or a gaseous oxidizing agent, for example N₂O, as well as mixtures thereof. Inert gasses, such as helium, argon or nitrogen may be used to dilute the gasses during the process.

Preferably the semiconductor layer and the first conductive layer each independently have a SRF of at least 10, at least 20, at least 50, at least 100, or at least 400, including 15, 25, 30, 40, 45, 60, 70, 80, 90, 150, 200, 300, 500, 600, 700, 800, 900 and 1000. Particularly in the case of a dye-sensitized solar cell, the greater the surface area the larger the amount of dye that may be loaded onto the semiconductor layer surface. As the amount of dye loading increase, the amount of light which is absorbed and converted into electron-hole pairs increases, increasing the total amount of powder generated by the device. There are a variety of techniques available to increase the SRF of the semiconductor layer. For example, the semiconductor layer may be deposited on the first conductive layer, where the first conductive layer itself has a high SRF. The high SRF of the first conductive layer may be obtained, for example, by chemical etching of the first conductive layer, or by sintering fine particles of the material of the first conductive layer onto a planar layer of the same or a different material. Alternatively, templates, for example formed polystyrene, may be used during formation of the first conductive layer, and/or the semiconductor layer to provide a high SRF; multiple templated layers may also be formed. Combinations of these techniques are also possible.

The absorption of light may also be enhanced by forming the semiconductor layer into a light trapping structure, such as a structure with long range order having a unit cell length on the order of the wavelength of the light which is to be absorbed, also referred to as a photonic crystal. For example, a template of polystyrene beads having a diameter of 100 to 1000 nm, including 150, 200, 250, 300, 350, 400, 450, 500, 550, 600, 650, 700, 750, 800, 850, 900 or 950 nm, may formed into 1-10 layers, including 2, 3, 4, 5, 6, 7, 8 or 9 layers. The layers will often self-organize into an ordered structure, for example a close-packed hexagonal structure. When used as a template for the first conductive layer, an inverse-opal structure may be formed, which will diffract light, causing it to scatter repeatedly and thereby increase the path length of the light through the structure, enhancing the likelihood of absorption of the light; other photonic crystal structures may be used. Multiple layers may also be formed, where each layer or set of layers is formed using different sizes of polystyrene beads, so that each layer or set of layers will have a different unit cell length, to increase the number of wavelengths of light which will be diffracted. Subsequent etching or an increase in the total number of layers may be used to increase the SRF of the structure. Other light trapping structures may also be used.

As shown in FIG. 1B, an optional blocking layer may be present on the semiconductor layer. The blocking layer, which serves to bind defective sites on the semiconductor layer and suppress back electron transfer, preferably has a different composition than the semiconductor layer, and is preferably a transparent insulating material, for example magnesium oxide (MgO), aluminum oxide (Al₂O₃), zirconium oxide (ZrO₂), boron nitride (BN), silicon oxide (SiO₂), diamond (C), barium titanate (BaTiO₃), and mixtures thereof. The blocking layer may also be formed of a transparent semiconductor material as long as it is not the same composition as the semiconductor layer and is an n-type semiconductor, for example titanium dioxide (TiO₂), zinc oxide (ZnO), zirconium oxide (ZrO₂), tungsten oxide (WO₃), molybdenum oxide (MoO₃), lead oxide (PbO), and mixtures thereof, or mixtures thereof with a transparent insulating material. The blocking layer may be formed by the same techniques as the semiconductor layer. As with the semiconductor layer, it is important that the blocking layer both conformal and compact.

The optional blocking layer preferably has a thickness of at most 2 nm, or may be present in an amount of at most 10 atomic layers. It may also be present as islands on the surface of the semiconductor layer, in which case the thickness may be expressed as an average thickness across the semiconductor layer, for example as less than one atomic layer.

Optionally, a colored material may be on the surface of the semiconductor layer and/or the optional blocking layer. Preferably, the colored material, a chromophore, may be pigments and/or dyes; dyes are especially preferred. Typically, dyes containing a platinum group metal (Ru, Rh, Pd, Os, Ir and Pt) have been used for dye-sensitized solar cells. The enhanced charge separation and charge transport properties of the present invention, however, allow for non-platinum group metal containing dyes, metal free dyes, and even pigments, to be used to increase the wavelengths of light which the photovoltaic device may absorb. Examples of dyes include polypyridyl ruthenium dyes such as cis-bis(isothiocyanato) bis(2,2′-bipyridyl-4,4′-dicarboxylato)-ruthenium(II) bis-tetrabutylammonium (N719), tris(2,2′-bipyridyl-4,4′-carboxylate)-ruthenium (II) and tri(cyanato-2,2′,2″-terpyridyl-4,4′,4″-tricarboxylate)-ruthenium(II), copper bipyridine dyes such as 2,9-dialkyl-diphenyl-1,10-phenathrolinedisulfonate, hemicyanine dyes such as (E)-N-(3-sulfopropyl-4-[2-(4-dimethylaminophenyl)ethenyl]pyridinium, (E)-N-(3-sulfopropyl-4-[2-(4-dimethylaminophenyl)ethenyl]quinolinium, (E)-N-(3-sulfopropyl-4-[2-(4-N-methyl-N-hexadecylaminophenyl)ethenyl]pyridinium and (E)-N-(3-sulfopropyl-4-[2-(4-N-methyl-N-hexadecylaminophenyl)ethenyl]quinolinium, phenanthroline complexes dyes of Fe, Ru, Os, Pd, Rh or Ir, such as those described in U.S. Pat. No. 6,278,056 to Sugihara et al., and methylene blue. It is also possible to modify the surface of the semiconductor layer into a light-absorber, thereby making the semiconductor layer self-sensitizing, for example by reducing the titanium oxide to a suboxide.

As illustrated in FIG. 1A, an electrolyte, which contains a solvent and a redox mediate, is in contact with the semiconductor layer and an electrode. Preferably, the electrolyte is not in contact with the first conductive layer. In some cases, an insulating or semiconductor layer may be formed on a portion of the first conductive layer to prevent contact between the electrolyte and the first conductive layer. The solvent may be any liquid or solid which allows for diffusion or transport of the redox mediator. In some cases, a polymeric or solid redox mediator may be used, in which case an electrolyte may be eliminated. Preferably, the solvent is a polar solvent, such as water, polar organic liquids such as alcohols, amides, glycols such as ethylene glycol, and/or polar inorganic liquids, including liquid salts and ionic liquids.

Typically, the redox mediator used in a dye-sensitized solar cell was required to cause reduction of the dye cation slowly enough to allow for charge separation of the electron-hole pair. Consequently, a slow redox mediator, such as I⁻/I₃⁻ was required. However, the present invention carries out charge separation and charge transport quickly enough that much faster redox mediators may be used. Redox mediators include molecular redox mediators, including ferricyanide, 2,6-dimethyl-1,4-benzoquinone, phenazine ethosulfate, phenazine methosulfate, phenylenediamine and 1-methoxy-phenazine methosulfate, as well as pyrroloquinoline quinone, benzoquinones and naphthoquinones, N-oxides, nitroso compounds, hydroxylamines, oxines, flavins, phenazines, phenothiazines, indophenols and indamines. Other organotransition metal complexes and transition metal coordination complexes may also be used, such as ferrocene, 1,1′-dimethyl ferrocene and ruthenium hexamine. Polymeric redox mediators may also be used; these include polymers which contain one or more molecular redox mediators, attached to a polymeric molecule. Polymeric redox mediators are also described in Moyo et al. (Sensors, 12, 923-953 (2012)), and Patent Application Publication, Pub. No. US 2009/0202880.

Electrochemical impedance spectroscopy (EIS) is an effective technique for elucidating the competition between the electron lifetime, (recombination kinetics of electrons with oxidizing species in the surrounding electrolyte, for example the redox mediator and dye cation) and the electron diffusion kinetics to the first conductive layer. accordingly, EIS may be used to determine if a slow redox mediator, such a I⁻/I₃⁻ in ethylene glycol, is necessary, or if a different and fast redox mediator, such as ferrocene, may be used.

The electrolyte may also be replaced with a solid p-type semiconductor, for example CuI, CuSCN, CuAlO₂, NiO, and mixtures thereof, as well as p-doped conductive polymers. The p-type semiconductor has a different composition that the semiconductor layer. Conductive polymers include poly(acetylene)s, poly(pyrrole)s, poly(thiophene)s, polyanilines, polythiophenes, poly(p-phenylene sulfide), poly(para-phenylene vinylene)s (PPV) and PPV derivatives, poly(3-alkylthiophenes), polyindole, polypyrene, polycarbazole, polyazulene, polyazepine, poly(fluorene)s, and polynaphthalene. Other examples include polyaniline, polyaniline derivatives, polythiophene, polythiophene derivatives, polypyrrole, polypyrrole derivatives, polythianaphthene, polythianaphthane derivatives, polyparaphenylene, polyparaphenylene derivatives, polyacetylene, polyacetylene derivatives, polydiacethylene, polydiacetylene derivatives, polyparaphenylenevinylene, polyparaphenylenevinylene derivatives, polynaphthalene, and polynaphthalene derivatives, polyisothianaphthene (PITN), polyheteroarylenvinylene (ParV), in which the heteroarylene group can be for example thiophene, furan or pyrrol, polyphenylene-sulphide (PPS), polyperinaphthalene (PPN), and polyphthalocyanine (PPhc), and their derivatives, copolymers thereof and mixtures thereof. As used herein, the term derivatives means the polymer is made from monomers substituted with side chains or groups. P-doping of the solid semiconductor and the conductive polymers may be carried out chemically, if necessary, for example by treatment with an oxidizing agent, such as oxygen, fluorine or iodine, or by electrochemical oxidation.

An electrode is in contact with the electrolyte or the solid p-type semiconductor. The electrode is preferably formed of a highly conductive and chemically unreactive material, for example gold, platinum, or metallic alloys. The electrode may be present on a second conductive layer, which may be formed of any conductive material. It is also possible to combine both the electrode and the second conductive layer into a single layer. The electrode and second conductive layer serve to transport electrons back to the electrolyte or the solid p-type semiconductor, thus completing the electrical circuit. The second conductive layer is preferably on a support, which may be formed of any solid material, such as plastic, glass or metal.

### Examples

FTO—TiO₂ Core-Shelled Conformal Nanoparticulate Photoanode

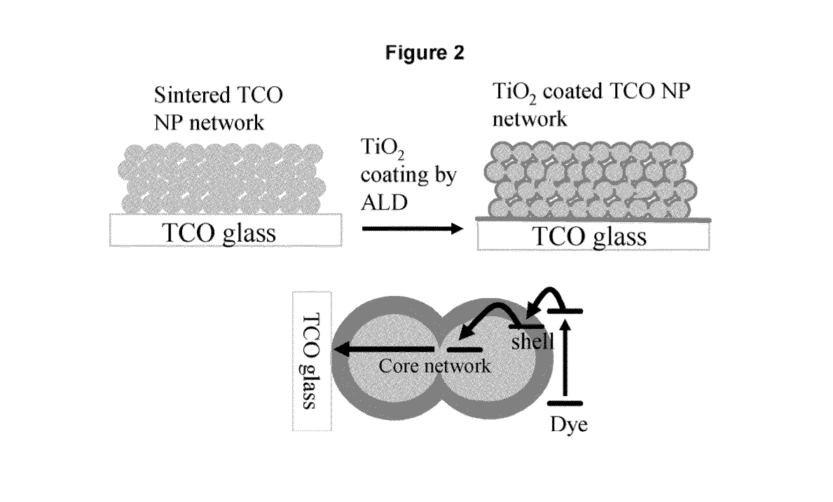

To overcome the above challenges, we intend to aggressively transform the 2-D planar transparent conductive oxide (TCO) to 3-D nanoparticulate TCO network. We herein use DSSCs as an convenient exploratory platform to embody the advantages of this strategy, but the concept can also be suitable for other types of PV systems. For DSSCs, directly sensitizing TCO is not suitable because the low conduction band (CB) edge of TCO (˜−4.8 eV vs Vac.) can lead to low attainable photovoltage in comparison with TiO₂ or ZnO (−4.2 eV vs Vac). In addition, TCO must be isolated from the electrolyte to avoid back electron transfer from TCO to redox shuttle and dye cations (shunt leak). As such, we present a 3-D TCO/PV conformal core-shelled nanoparticulate architecture. The use of TCO nanoparticles can retain the large surface area for light absorption. As depicted in FIG. 2, TCO nanoparticles are sintered into TCO nanoparticle network to serve as an integral electron-collecting anode. Next, all the surfaces of the TCO are to be coated with a thin and conformal layer of TiO₂ using atomic layer deposition (ALD) technique, followed by dye sensitization of the resulting ALD-TiO₂ layer. The sensitized TiO₂ layer provides matching conduction band-edge with respect to dye molecules (N719), and reduces the shunt leak from TCO to electrolyte and dye cations. Compared to the electron diffusion distance (dₑ) of >10 μm in the conventional TiO₂ NP-based photoanode, this configuration yields a dₑ in TiO₂ layer of only a few tens of nm defined by the thickness of the ALD TiO₂ layer, a factor of 10²˜10³ times reduction in comparison to a conventional 10-μm-thick sensitized TiO₂ NP-based PV layer.

Furthermore, the conformal TCO (core)-TiO₂ (shell) nanoparticulate photoanodes can further enhance the charge separation by taking the full advantage of a built-in potential at the TCO/TiO₂ interfaces. Explicitly, to counter-balance the Fermi level difference in TCO (˜−4.8 eV vs vac.) and TiO₂ (˜−4.4 eV vs vac.), electrons have to flow from TiO₂ to TCO layer at the interfaces, forming a space charge layer at the TCO/TiO₂ interface. This space charge layer creates the built-in potential, which helps sweep electrons from TiO₂ layer into TCO layer through drfting. However, in the conventional photoanodes consisting of a thick layer of TiO₂ or ZnO-based nanostructures on a flat TCO substrate, the overall role of this built-in potential is negligible, because the width of the space charge layer spans only ˜30 nm adjacent to the TCO substrate. As such, majority transport in the rest of the thick TiO₂ or ZnO layers is not affected, and still undergoes inefficient ambipolar diffusion. In contrast, in our TCO (core)-TiO₂ (shell) nanoparticulate photoanode, the TCO/TiO₂ interface are omnipresent so that the built-in potential at TCO/TiO₂ interface can be significantly exerted to alter the elementary charge separation and transport processes.

Results and Discussion

We chose fluorinated tin oxide (FTO) as the TCO materials in this work. FTO is generally considered as a degenerate semiconductor (metallic behavior) when highly doped (>10²¹ cm⁻³). However, due to its low dielectric contact (∈ᵣ=9), FTO has a non-negligible electric field region (depletion layer) at its interface with the electrolyte. This built-in electric field is adopted in our system to accelerate the electron transport at the interface between FTO and electrolyte. For practical applications, FTO offers a better thermostability than indium-tin oxide, and fluorine has higher natural abundance than indium.

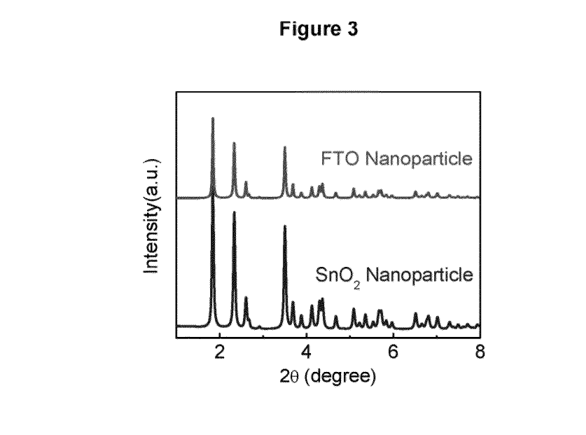

A high energy X-ray probe is used to examine the crystal structure of the prepared FTO nanoparticles under diffraction mode. FIG. 3 shows the XRD pattern of FTO nanoparticles synthesized and sintered at 600° C. The major peak centered at 2θ=1.7° is ascribed to the (110) preferential orientation. The peaks at 2.26°, 2.71° and 3.58° are associated with the (101), (200), and (211) orientation, respectively. The spectrum clearly reveals the presence of crystalline FTO with the tetragonal structure, and agrees well with the crystal phase of pure SnO₂. However, the peaks associated with dopant fluorine can not be detected from XRD even under high-energy X-ray. The presence of fluorine doping in SnO₂ was identified by XPS measurement.

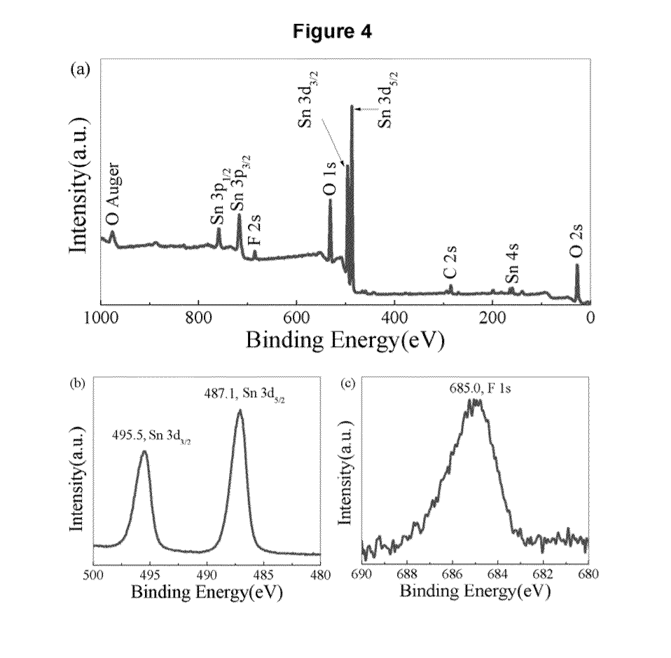

X-ray photoelectron spectroscopy (XPS) experiments were performed to elucidate the chemical state of elements in the FTO nanoparticles. FIG. 4a shows the survey XPS spectrum and FIGS. 4b and 4c are the high-resolution XPS spectrum of Sn_{3d} and F₁ₛ. The survey spectrum (FIG. 4a) clearly indicates that Sn, O and F elements exist in the FTO nanoparticles, with only trace impurity of carbon, owing to the adventitious hydrocarbon during sample preparation. The Sn 3d_{5/2} and Sn 3d_{3/2} spin-orbital splitting photoelectrons for FTO were located at binding energies of 487.1 and 495.5 eV (FIG. 4b), respectively, assigned to the presence of a typical Sn⁴⁺ and also indicated that Sn—F bonding formed in the FTO nanoparticles. The evaluation of binding energy values for the F1s peaks show that they are in the ranges 684.7-685.2 eV (FIG. 4c). These values can be attributed to F in SnF₄. This further illustrates that F ions are successfully doped into the SnO₂ lattice.

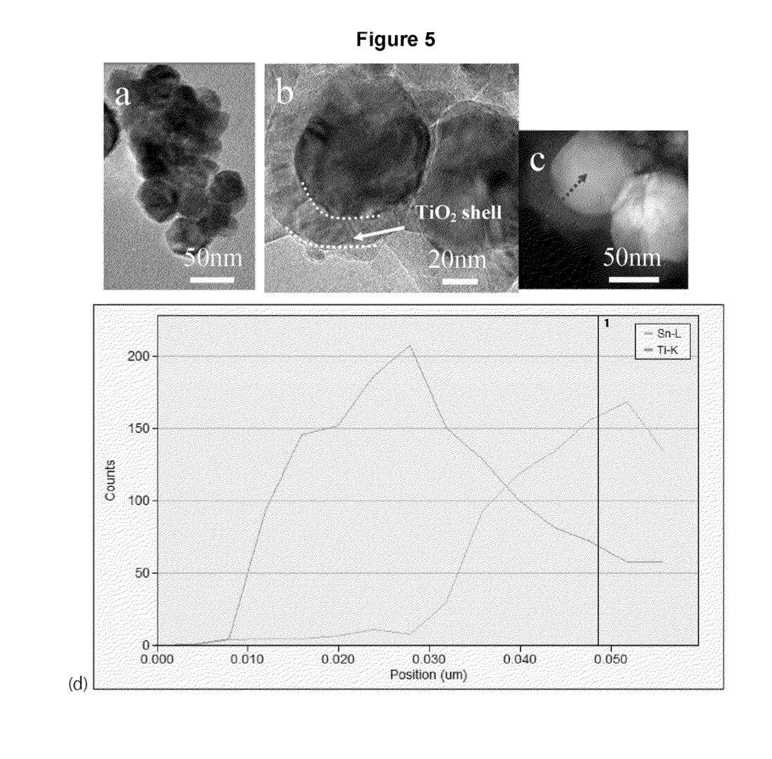

The electron blocking layer is crucial to passivate the surfaces of conductive FTO nanoparticles and thus reduce the shunt leakage in order to achieve efficient electron transport in DSSCs. FTO nanoparticles are first synthesized and sintered together to form FTO nanoparticulate layer on a planar FTO substrate in order to maintain the integrity of the FTO core thus good electron transport properties. Then, a conformal shell layer of TiO₂ is desired to cover all surfaces of the FTO nanoparticulate film. To achieve homogeneous and throughout coverage, ALD is used to coat a conformal TiO₂ shell layer on FTO nanopartice (NP) film since ALD is a layer-by-layer deposition technique and can achieve high infiltration and produce high quality films with less pinholes on various morphologies. In FIG. 5, the depth profile of the ALD TiO₂ layer was studied by scanning transmission electron microscopy (STEM) coupled with electron energy loss spectroscopy (EELS).

FIG. 5a shows the typical result from STEM investigation on the sample morphologies. FIG. 5b is the magnified image of the portion of the connected FTO nanoparticles. The core-shelled structure is clearly presented. The average particle size of the synthesized FTO is around 60 nm. It also reveals that the deposited ALD TiO₂ layer is compact and uniform. FIG. 5c shows the dark field image of a typical conformal TCO (core)-TiO₂ (shell) nanoparticulate photoanodes, in which the FTO core particles are sintered together, and wrapped by the TiO₂ shell. In FIG. 5d, the corresponding profile of EELS line scans were acquired across the core-shelled FTO indicated by the arrow in FIG. 5c. For a core/shell structure, the EELS signal of the shell material is expected to be proportional to the thickness of the shell in the z direction (i.e., normal to the plane of incidence). Therefore, the intensities of the Ti, and Sn signal change with the probe position across the measured portion. As the electron beam scans from the edge to the center, only Ti signal is detected and grows because the e-beam impact more Ti when it scans from edge to center, while no Sn signal is observed in the portion near the edges region (approximately ˜20 nm). As the electron-beam approaches the center, Sn signals start to grow. The TEM study clearly confirms the conformal TCO (core)-TiO₂ (shell) nanoparticulate structure.

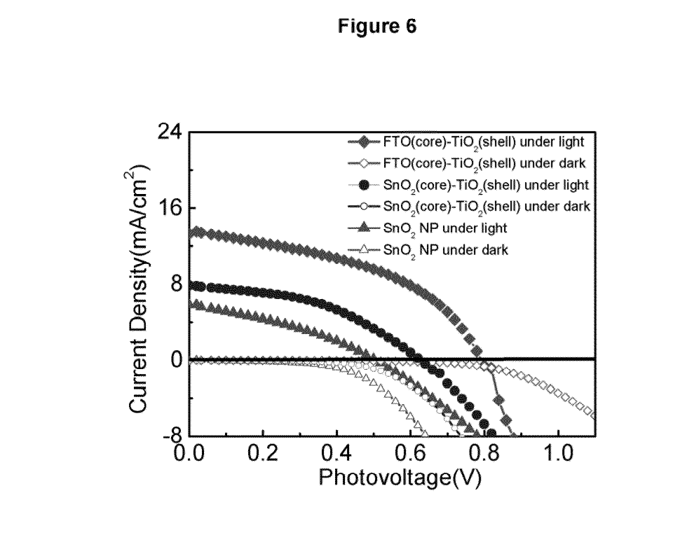

The photovoltage and photocurrent behaviors of DSSCs based on the conformal TCO (core)-TiO₂ (shell) nanoparticulate photoanodes were characterized under the simulated AM 1.5 illumination (100 mW/cm²). Typical J-V curve for DSSCs is shown in FIG. 6. For a fair comparison, a conventional DSSC, i.e., samples based on undoped SnO₂ nanoparticles with/without TiO₂ coating were also measured. The resulting photovoltaic parameters from the J-V measurement are summarized in Table 1, including open circuit voltage (V_{oc}), short-circuit current (J_{sc}), energy conversion coefficient (η), and fill factor (FF).

TABLE 1
Averaged photovoltaic parameters of DSSCs based on five pairs of
samples, including conformal FCO(core)-TiO₂(shell) nanoparticulate
DSSCs, and undoped SnO₂ NP-based DSSCs (with and without
TiO₂ shell) with same thickness and dye loading amount.

| | J_{sc} | V_{oc} | | |
|---|---|---|---|---|
| | (mA/cm²) | (mV) | FF | η (%) |
| FTO(core)- | 13.0 ± 0.30 | 760 ± 20 | 0.48 ± 0.02 | 4.6 ± 0.2 |
| TiO₂(shell)- | | | | |
| SnO₂(core)- | 7.6 ± 0.20 | 600 ± 20 | 0.45 ± 0.03 | 2.1 ± 0.2 |
| TiO₂(shell) | | | | |
| SnO₂NP-based | 5.6 ± 0.20 | 480 ± 20 | 0.33 ± 0.02 | 1.0 ± 0.02 |
| DSSC | | | | |

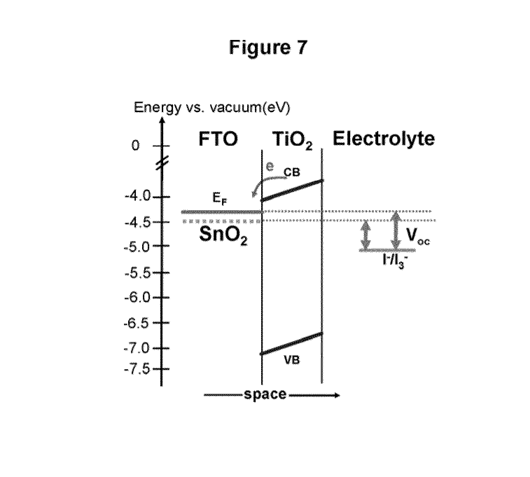

It is clear that the samples using conformal TCO (core)-TiO₂ (shell) nanoparticulate photoelectrode exhibit a highest current density in comparison to the corresponding control samples by a factor of 1.6 in J_{sc}. Furthermore, the V_{oc} of DSSCs based on our conformal TCO (core)-TiO₂ (shell) nanoparticulate photoanode were measured to be consistently about 770 mV, much greater than the values for undoped SnO₂ NPs-based DSSCs, either shelled with TiO₂ or not shelled as summarized in Table 1. Reported V_{oc} values for bare SnO₂ NP are also below 600 mV. V_{oc} is determined by the energy gap between the quasi Fermi level of the photoanode (SnO₂ NPs) under illumination and the redox potential of the I⁻/I₃⁻. With heavy doping of F, the Fermi level of FTO rises due to Burstein-Moss shift, and the nearly metallic behavior of FTO enable it to accommodate more photoelectrons so as to charge the quasi-Fermi level up to the CB edge of TiO₂ shell (FIG. 7). In contrast, bare SnO₂ has much less density of states for accommodating photoelectrons, which leads to its poor V_{oc}. Such an argument can also be evidenced by the higher onset of dark current for our conformal TCO (core)-TiO₂ (shell) nanoparticulate photoanode in comparison to the much lower onsets for bare SnO₂ NP (FIG. 6).

The electrical conductivity of the pellets prepared by compressing the corresponding FTO and updoped SnO₂ nanoparticles was quantitatively studied using the four-probe method. As a reference, the anatase TiO₂ nanoparticle pellet was also measured and these values were summarized in Table 2. Apparently, pellets made from FTO NPs exhibits the highest conductivity, two orders of magnitude greater than that of undoped SnO₂ and TiO₂ nanoparticle. Note that updoped SnO₂ also shows certain conduction due to oxygen vacancies. Fluorine doping results in a significantly enhanced conductivity with 0.27 S/cm. The enhanced conductivity in the FTO particles significantly improve the charge transport through the conformal FCO (core)-TiO₂ (shell) network.

TABLE 2
The nominal conductivity of the pellets of the nanoparticles
measured by four-probe method.

| Sample | FTO | Pure SnO₂ | TiO₂ |
|---|---|---|---|
| Conductivity σ(S/cm) | 0.27 | 0.045 | 4.53 × 10⁻⁹ |

Furthermore, our conformal FTO (core)-TiO₂ (shell) nanoparticulate photoanodes can take full advantage of the built-in potential at FTO/TiO₂ interface. Because the Fermi level of FTO is lower than the conduction band of TiO₂, electrons have to flow from TiO₂ to FTO (forming a space charge layer) in order to reach thermodynamic equalibrium. The width of this space layer (w) is about ˜30 nm, which can be estimated by w=\sqrt{2_{∈0}V_{b}/(eN_{d})}, where the built-in voltage V_{b} is related to the Fermi level difference between TiO₂ and FTO, and N_{d} is the carrier concentration in TiO₂ (V_{b}=˜0.2V, Nd is ˜10¹⁷/cm³ for TiO₂). Under non-equilibrium states (i.e. illumination), photoelectrons in TiO₂ tend to flow into the FTO. As such, this interface built-in potential favors charge separation and transfer. However, in conventional TiO₂ NP|planar FTO based DSSCs, the influence of this built-in potential on overall transport is negligible because it only spans ˜30 nm thick (i.e 1-2 layers of TiO₂ NPs) at the interface of the TiO₂ NP and planar FTO, while majority transport occurs in the over 10 μm thick NP layer. In contrast, as the FTO/TiO₂ interface becomes omnipresent in our conformal FTO (core)-TiO₂ (shell) nanoparticulate photoanode, the built-in potential at FTO (core)/TiO₂ (shell) interface becomes a pronounced factor to assist transport. We see signs of drift transport in EIS studies as delineated below.

When benchmarked with surface roughness factors (SRF), the DSSCs based on our conformal FCO (core)-TiO₂ (shell) nanoparticulate photoanodes exhibit better efficiencies than the literature reported highly optimized TiO₂ nanocrystalline-based DSSCs. For example, for 8 μm-thick conformal FCO (core)-TiO₂ (shell) photoanode (˜60 nm in diameter) films, the surface roughness factor is 400, and the measured average energy conversion efficiency is 4.8%, in comparison to 3.2% for the TiO₂-NP based DSSCs (25 nm in diameter, ˜6 μm in thickness, SRF=900). This value is also certainly much better than the undoped SnO₂ NP-based DSSCs (2.1% in efficiency based on the same thickness and SRF).

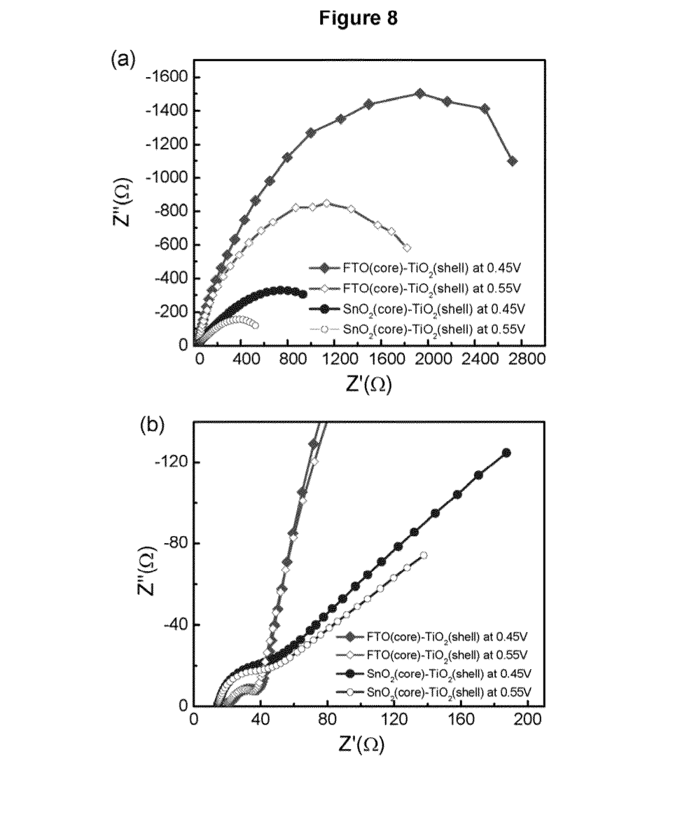

We then investigated the time constants of the two kinds of the DSSCs using electrochemical impedance spectroscopy (EIS). EIS is an effective technique for elucidating the competition between the electron lifetime, (i.e. recombination kinetics of electrons in DSSCs. network with oxidizing species in the surrounding electrolyte e.g. I₃⁻ and dye⁺) and the electron diffusion kinetics to the collecting TCO anode. FIG. 8a compares the Nyquist plot of an updoped SnO₂ NP film with that of a conformal FTO (core)-TiO₂ (shell) nanoparticulate DSSC. The impedance data were measured at a forward bias of −4.5 V and −5.5V in the dark at 20° C. in the presence of iodide/tri-iodide redox electrolyte. An enlarged diameter of the semicircle was observed in the low frequency range (right) from FTO NP-DSSC compared to that of the undoped SnO₂ NP film. Because this diameter corresponds to the resistance of heterogeneous charge transfer (R_{ct}) from the conduction band of the semiconductor to tridiodide ions in the electrolyte, the increase indicates that the FTO (core)-TiO₂ (shell) leads to a pronounced reduction in the dark current. The very small semicircle magnified in FIG. 8b at high frequency is assigned to the resistance of Pt and capacitance Cₚₜ of the electrolyte|Pt cathode interface. All the EIS spectra were fitted by using Z-View software with an equivalent circuit (inset in FIG. 8c) which is based on the general transmission line mode.

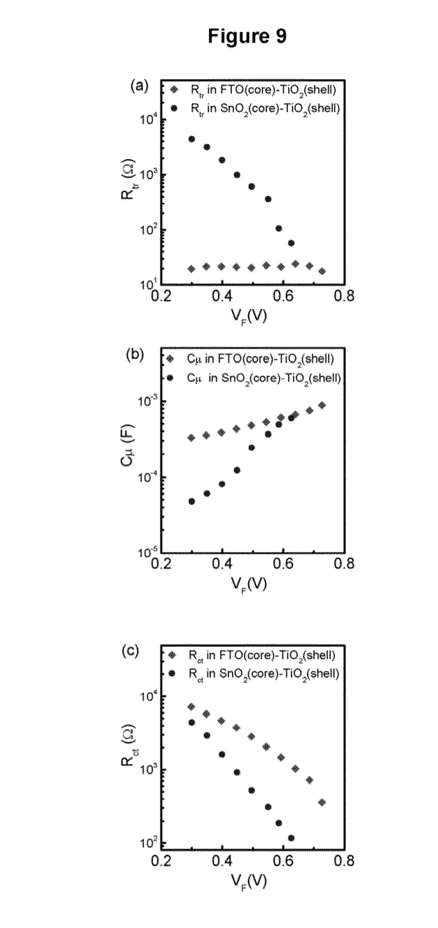

To investigate the origin of the high V_{oc} obtained for FTO cell, we plot the fitted parameters (Rₜᵣ, R_{ct}, C_{μ}) as a function of the Fermi level (V_{F}) in the sensitized photoanode for the cells. V_{F}, the internal voltage, is obtained by subtracting the effect of the series resistance and counter electrode charge transfer resistance on both Rₜᵣ and C_{μ} as follows: V_{F}=Vₐₚₚ−Vₛ−V_{CE}, where Vₛ and V_{CE} are the potential drop at the series resistance and at the counter electrode, respectively. FIG. 9a plots the transport resistance (Rₜᵣ) of the cells analyzed and 9b plots the chemical capacitance against V_{F}, respectively.

For pure SnO₂ cell we see that the resistances Rₜᵣ, R_{ct}, and the capacitance (C_{μ}) of the film follow the same behavior as in the case of TiO₂ samples formed of the nanoparticulate networks described in other reports. An exponential decrease of the Rₜᵣ is observed with increasing the voltage. A nearly constant value of the capacitance is obtained at low potentials, followed by an exponential increase because electron accumulation in the Fermi level of SnO₂ rises up with the potential.

However, in FTO (core)-TiO₂ (shell) based DSSC, the values of Rₜᵣ are much smaller and nearly constant with bias. The capacitance varies relatively slowly with bias as the FTO is kept with a larger concentration of electrons independently of the applied voltage. The effect of doping on the capacitance is also relevant, which obeys Mott-Schottky characteristics in highly doped case. Intrinsic SnO₂ shows poor conductivity, as has been discussed above, which restricts the charge transport from SnO₂ to FTO collecting electrode, reducing the cell performance. Therefore, improved conducting property of semiconductor allows the rapid electron flow from Fluorine doped SnO₂ to planar FTO collecting electrode. The interfacial charge recombination resistance (R_{ct}) of both cells decreases exponentially with the increase of the applied voltage (FIG. 9c).

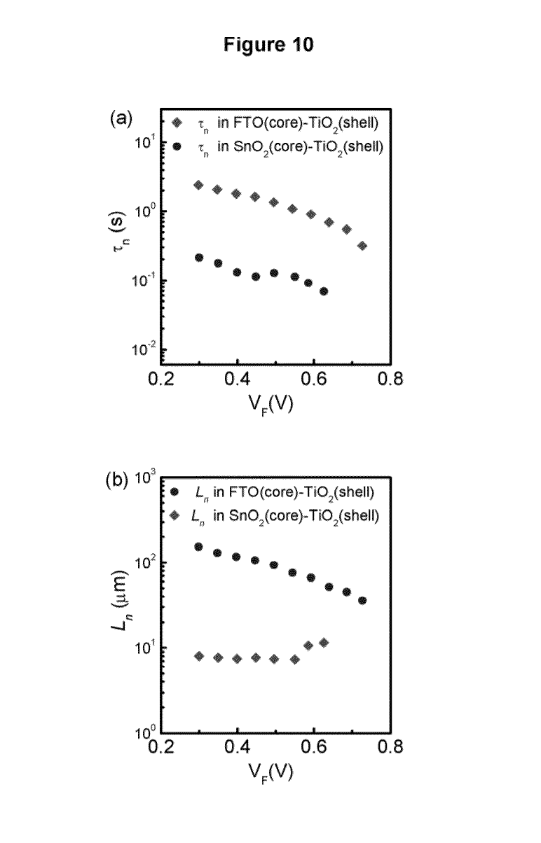

If the capacitance C_{μ} is taken to be strictly “chemical” in nature (reflecting density of states), it is rational to assume a multiple trapping diffusion interpretation in which Tₙ=R_{ct}C_{μ}. FIG. 10a is the comparison in charge lifetime (Tₙ) for the FTO (core)-TiO₂ (shell) based DSSC and pure SnO₂ DSSC. Tₙ decreases exponentially with the increase of the applied voltage for all the cells. Due to an increase of R_{ct} and C_{μ} with doping and TiO₂ coating, the electron lifetime for the FTO (core)-TiO₂ (shell) photoanode DSSC exceeds that of pure SnO₂ cell at all applied voltages. The longer electron lifetime in the FTO (core)-TiO₂ (shell) cell shows the remarkable inhibition of the charge recombination at the oxide/dye/electrolyte interface. This enhancement in slower recombination process can be attributed to the significantly reduced collection distance, namely the thickness of the TiO₂ layer in our FTO—TiO₂ core-shell structure in comparison to pure SnO₂ nanoparticle-based solar cells. Also the faster electron transport in fluorinated tin oxide limits the back electron transfer. Hence, more electrons can reach the collecting electrode, which results in an enhanced J_{sc} in our device as indicated in Table 1. Meanwhile, the faster electron collection helps the accumulation of electrons in the conduction band of SnO₂, leading to the rise of the chemical potential of electrons in the electrode, thus increasing V_{oc}.

Materials and Methods

Synthesis of Fluorine Doped SnO₂ Nanoparticle

The procedure for preparing the F-doped SnO₂ nanoparticles is described as following. First, 1.98 g SnCl₂.2H₂O (99.0%), 0.74 g NH₄F, 0.35 g starch were completely dissolved in 30 ml DI H₂O at 70° C. Under stirring, 25% concentrated NH₃.H₂O was added dropwisely to the solution to adjust the pH of solution to 10-11. The color of solution turns to pale yellow as the NH₃.H₂O increased. Next, the resulting suspension was placed in the water bath at 70° C. with continuous stirring until most of the solvent was evaporated. Then the slurry was dried at 120° C. in the oven overnight to remove the residue solvent. Finally, the powder was ground completely in an agate mortal and further thermally calcinated at 550° C. for 2 h. The resulting powder was pale gray. The pure SnO₂ particles were synthesized using the similar procedure without adding NH₄F.

Alternatively, a paste-like mixture containing FTO precursory solution as described above, the pre-synthesized FTO nanoparticles as described above, and surfactants such as polyethylene glycol, and diblock copolymers such as poly(ethylene-co-butylene)-b-poly(ethylene oxide), or PS-b-PEO (Polymer Source Inc.), and thickening agents such as POLYOX WSR-30 (water-soluble resin, the DOW Chemical Company), is speaded on a FTO glass and sintered at 500-550° C.

Photoelectrode Preparation and Surface Modification

The results reported in this work were obtained with the electrodes prepared from the synthesized F-doped SnO₂ nanoparticles. In a typical sample preparation process, a slurry solution of FTO and pure SnO₂ nanoparticles were as prepared respectively by grinding a mixture of 0.1 g FTO powder, 20 μl acetic acid, 100 μl DIH₂O, 200 μl ethanol. The particle dispersions in the mortar were transferred to a small beaker by 2 ml ethanol and then 600 μl ethyl cellulose (5% ethanol solution) and 0.3 g Terpinol were added into the mixture, followed by stirring and sonication. The contents in dispersion were concentrated by evaporating at 35° C. under stirring. The pastes were finalised with a grinder. Scotch tape was used to define the area to be coated with FTO powder film. Approximately 20 μl/cm² paste was uniformly spread onto the entire FTO substrate. A doctor blade was used to scratch off excessive paste above the scotch tape and the FTO paste film was vertically pressed by a press to assure the uniform thickness on all sample areas. The samples were dried at room temperature for 30 min prior to sintering at 500° C. for 30 min (temperature rising rate=1° C./minute). This process yielded an approximately 8 μm-thick FTO NP (60 nm in diameter) film confirmed by scanning electron microscope.

For the surface modification of FTO nanoparticulate-based electrode, ALD method was employed to form a thin layer of dense coating as electron blocking layer on the FTO surface. ALD is the most suitable technique to produce high quality films with excellent reproducibility and superior conformal growth on various morphologies. The FTO samples were coated with TiO₂ by ALD (Cambridge Nanotech Savannah 200) at 200° C. using titanium tetraisopropoxide (TTIP, Aldrich) at 80° C. and H₂O at room temperature. The pulse/exposure/purge sequence for TTIP was 1.5s/5s/20s and for H₂O was 0.015s/5s/20s. The growth rate was estimated to be ˜0.2 Å/cycle from ellipsometry on a witness Si chip that showed 14 nm of TiO₂. This rate is somewhat lower than those typically observed for TiO₂ ALD on flat substrates that do not required long precursor exposures (0.3 Å/cycle).

Prior to dye-loading, the photoelectrodes were heated to 80° C., then, they were immediately soaked in a 0.3 mM solution of cis-bis(isothiocyanato) bis(2,2′-bipyridyl-4,4′-dicarboxylato)-ruthenium(Π) bis-tetrabutylammonium (N719) in absolute ethanol for overnight. The samples were then rinsed with ethanol for 30 min to remove non-chemisorbed dye molecules. The dye-sensitized solar cells were assembled by sandwiching the FTO NP coated with TiO₂ photoanode with the Pt-coated FTO cathode using a piece of hot melt surlyn (25 μm thick, Solaronix) as a spacer. The internal space of the cell was filled with a commercial electrolyte EL-HSE (Dyesol) by capillary force. A black mask with a window area of 0.25 cm² was applied on the photoanode side to define the same active area for both devices.

Photoelectrode Characterization

In a typical experiment for probing the crystalline structural of the synthesized FTO nanoparticles, the fluorine doped SnO₂ powders and undoped SnO₂ were sealed in a small capton tube. XRD patterns were continuously collected in a high-energy (115 keV) synchrotron X-ray beam at Advanced Photon Source. The doping of Fluorine was confirmed by X-ray photoelectron spectra (XPS) measurements, which were carried out on an X-ray photoelectron spectrometer (ESCALAB MK II) using Al Kα (1486.6 eV) X-rays as the excitation source, with C 1s (284.6 eV) as the reference.

The morphology of the samples was observed with a scanning electron microscope (SEM, JEOL 400) and a transmission electron microscope (TEM, CMT300) using an accelerating voltage of 150 kV.

The conductivity of the synthesized FTO material was measured on the pellets of the FTO using four-probe method. Pellets (10 mm in diameter, 0.5 mm in thickness) of the powder materials were prepared using a press (pressure=30 MP). A constant current of 0.1 mA was supplied through the first and fourth probes, while the voltage is measured between the second and third probe. Current and voltage were supplied and measured by a HP 3458A Multimeter. The conductivity a of the compressed pellet can be calculated by the equation:

$$σ = ( \frac{ln 2}{π t} ) ( \frac{I}{V} ) .$$

The J-V curves of the solar cells were measured by a potentiostat (Gamry Reference 600) at one Sun 1.5 AM G provided by a solar simulator (Photo Emission Inc. CA, model SS50B). The Gamry Reference 600 potentiostat was equipped with an EIS 300 software to conduct the electrochemical impedance spectroscopy (EIS) study. The EIS spectra were obtained by applying open circuit voltage as forward bias potentials in a frequency range from 0.06 to 60 kHz with an AC amplitude of 10 mV.

Photovoltaic Studies on Nanoscale 3-D Photonic Crystal Inverse Opal FTO (IO-FTO, Core)-TiO₂ (Shell) Electrode

Rather than incrementally improving the transport property of PV materials, we sought out-of-the-box solutions to tackle this challenge by renovating the conventional planar TCO electrodes to 3-D nanoarchitectured TCO with enhanced optical trapping effect, while an ultrathin layer of PV materials is conformally coated onto the 3-D TCO to reduce the transport distance in PV layer. As such, the fundamentally conflicting interlinks between light harvesting and charge transport will be transformed so that they are synergistic with each other. We use DSSCs as an exploratory platform for this strategy.

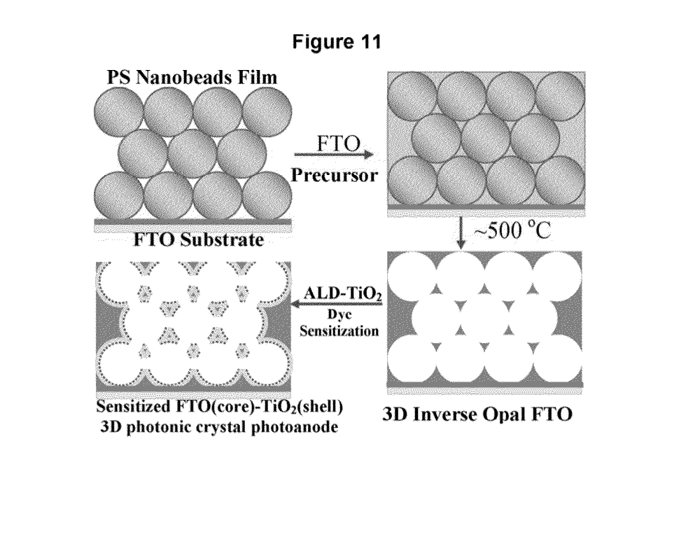

As schematically shown in FIG. 11, a 3-D photonic crystal (PhC) structured TCO electrode can be fabricated using polystyrene beads as a template. Then, a thin layer of wide bandgap semiconductor such as TiO₂ can be conformally coated on all surfaces of the TCO with controlled thickness by atomic layer deposition (ALD). Upon dye-sensitization, the TCO (core)-sensitized TiO₂ (shell) PhC structure is used as a photoanode in further DSSCs studies.

This innovative configuration brings up some unique advantages. First, the PhC structure can significantly enhance light-matter interactions, which enhances the light harvesting, or reduces the use of the expensive PV materials (e.g sensitized TiO₂ in DSSCs). Secondly, our TCO (core)-TiO₂ (shell) structured photoanodes can further enhance the electron transport by taking full advantage of a built-in potential at the TCO/TiO₂ interfaces. In this way, the logistics for light harvesting and charge transport are optimized, i.e. the transport process is mainly afforded by the highly conductive TCO layer, while the TiO₂ layer is mainly responsible for light harvesting and charge separation.

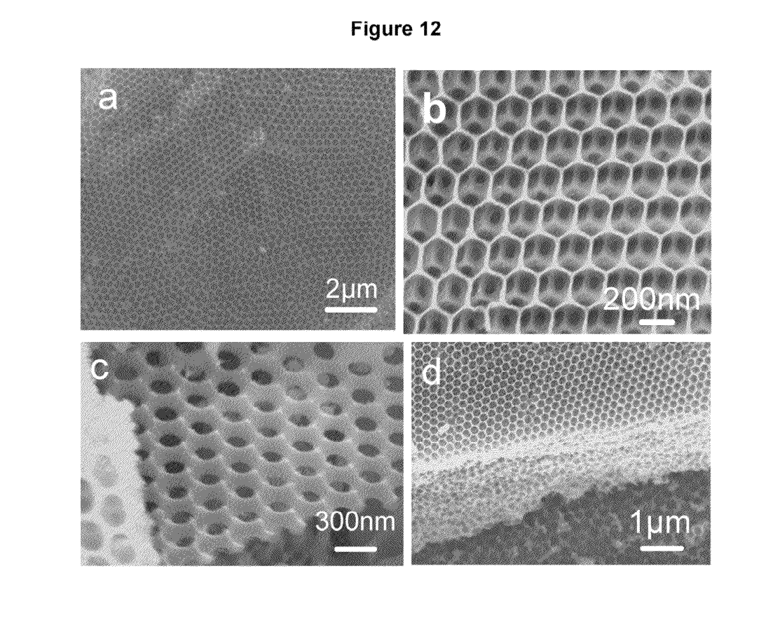

The synthesis of the IO-FTO electrodes was conducted through a facile, template-assisted method (Yang et al., Three-Dimensional Photonic Crystal Fluorinated Tin Oxide (FTO) Electrodes: Synthesis, Optic and Electrical Properties. ACS Applied Materials & Interfaces 2011, 3 1101.). The morphology of the electrodes was investigated by FE-SEM, and typical micrographs of a 2-μm IO-FTO layer synthesized are presented in FIG. 12. FIG. 12a shows a large area SEM topview of the IO-FTO structure. FIG. 12b, a magnified image, reveals that the top surface is composed of a closely packed, hexagonally ordered macroporous FTO. The diameter of the pores on this top layer is about 300 nm. The pore connectivity between top layers and sublayers can be clearly seen in FIG. 12b. FIG. 12c is a SEM image of a sliced piece of sample cleaved along the basal plane, which proves that the pores are all inter-connected throughout the matrix. This feature is crucial as, in the following procedures, it allows effective dye loading as well as unhindered electrolyte infiltration and diffusion throughout the photoanode, which assures effective mass transport for redox species. FIG. 12d is the cross-section view of the IO-FTO film, which shows the thickness of the resulting film is ˜2 μm.

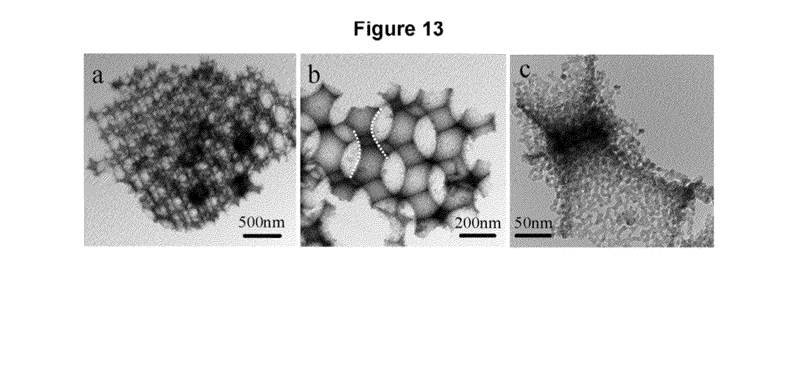

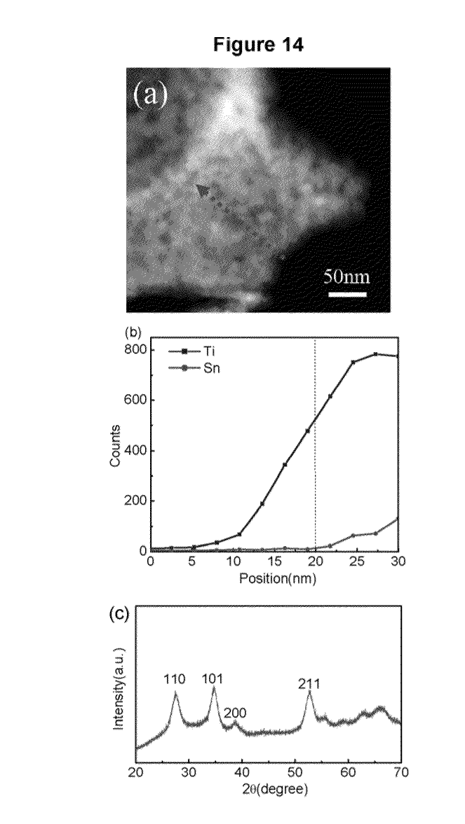

Further investigation on the sample morphologies were conducted by TEM, and typical results are shown in FIG. 13. These images clearly show the spatial periodicity of the closely packed micropores. In the low magnification image (FIG. 13a), the porous nature of the sample is clearly presented. FIG. 13b shows that the average pore thickness of the wall is about 50 nm. FIG. 13c is the magnified image of the portion defined by the white dashed line in FIG. 13b. It can be seen that the FTO wall is composed of fine nanosized SnO₂ crystallites (˜10 nm), which is consistent with the polycrystalline characteristic of the sample as studied by XRD (see FIG. 14c).

As we previously reported, the full coverage of the FTO surface with a thin electron-blocking layer is crucial to minimize the shunt leakage, which, otherwise, would result in an internal short circuit between the FTO anode and the cathode through electrolyte. Thus, atomic layer deposition method was utilized for conformal growth of a layer of TiO₂ on all internal surfaces of the IO-FTO. As a layer-by-layer deposition technique, ALD can achieve high infiltration and produce high quality, pinhole free films with excellent reproducibility on various morphologies. The IO-FTO samples were coated with 10 nm TiO₂ via ALD at 200° C. by using TiCl₄ and H₂O as Ti precursor and oxygen source, respectively. In FIG. 14, the depth profile of the ALD TiO₂ layer was studied by scanning transmission electron microscopy (STEM) coupled with electron energy loss spectroscopy (EELS).

FIG. 14a shows the dark field image of a typical isolated part of the IO-FTO. In FIG. 14b, the corresponding profile of EELS line scans were acquired across the wall of the IO-FTO indicated by the arrow in FIG. 14a. For a core/shell structure, the EELS signal of the shell material is expected to be proportional to the thickness of the shell in the z direction (i.e., normal to the plane of incidence). Therefore, the intensities of the Ti, and Sn signal change with the probe position across the measured portion. As the electron beam scans starting from the edge, only Ti signal is detected, while no Sn signal is observed in the portion near the edges for approximately ˜20 nm. As the electronbeam approaches the center, the Sn signal starts to grow. The TEM study clearly demonstrates the IO-FTO (core)-TiO₂ (shell) structure.

The crystal structure of the synthesized 3-D IO FTO was further studied by powder X-ray diffraction (XRD) in FIG. 14c. It shows that the diffraction peaks could be indexed as the SnO₂ tetragonal rutile phase shown in the previous study. As the thickness of the film is thin (˜2 μm) and the grain size is several nanometers, the peaks are broad without apparent preferred orientation. Nonetheless, the XRD of our IO-FTO films does not show any impurity peaks, indicating the high purity of the as-synthesized films.

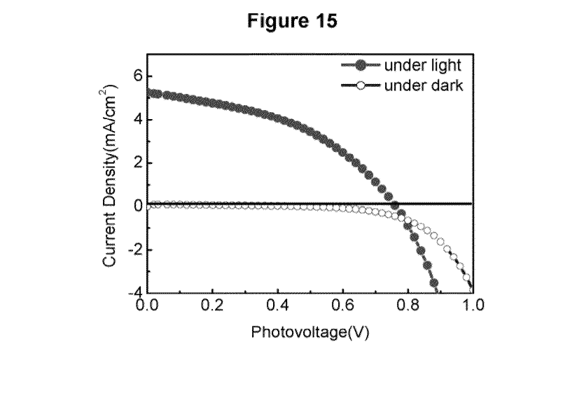

For photovoltaic study, DSSCs are constructed using our IO-FTO as photoanode, N719 dye as sensitizer, and I⁻/I₃⁻ as redox mediator. J-V curves of the cells were measured under standardized AM 1.5 illumination of 100 mW/cm² (active area 0.25 cm²). FIG. 15 shows the J-V curves of a best cell (η=1.9%) with 2 μm IO-FTO (core)-TiO₂ (shell) as photoanode. The key photovoltaic parameters averaged from 5 cells are summarized in Table 3. For comparison, parameters of DSSCs using (1) TiO₂ nanoparticle on a planar FTO, and (2) bare TiO₂ inverse opal as photoanodes on a planar FTO, are also included.

TABLE 3
Comparison of detailed photovoltaic parameters of DSSCs based on
our IO-FTO DSSCs (averaged from 5 samples), conventional TiO₂
Nanoparticle-based DSSCs, TiO₂ inverse opal based
DSSCs reported in the literature.

| | | J_{sc} | | | |
|---|---|---|---|---|---|
| | SRF | (mA/cm²) | V_{oc} (mV) | FF | η (%) |
| IO-FTO(core)- | 30 | 5.0 ± 0.2 | 740 ± 20 | 0.43 ± 0.02 | 1.7 ± 0.2 |
| TiO₂(shell) | | | | | |
| based DSSC | | | | | |
| TiO₂ NP DSSC | 90 | 4.3 | 770 | 0.61 | 2.0 |
| IO-TiO₂ DSSC | 120 | 4.97 | 692 | 0.62 | 2.2 |
| IO-TiO₂ | 100 | 4.7 | 740 | 0.52 | 1.8 |
| coupled | | | | | |
| with TiO₂ NP | | | | | |
| DSSC | | | | | |

For an N-layer FCC spheres in the photonic crystal structure, the SRF=N×2π/3^{1/2}. There are 8 layers voids (˜300 nm in diameter) in a 2 μm-thick IO-FTO (core)-TiO₂ (shell). Therefore, this film yields a surface roughness factor (SRF) of ˜30. This is a significant improvement compared to a flat FTO film, whose SRF is 1. The measured J_{sc} and η for our IO-FTO (core)-TiO₂ (shell) DSSCs are ˜5.0 mA/cm², and 1.7%, respectively. These values are comparable to those of a conventional 0.9 μm-thick TiO₂ nanoparticle (SRF≈90) supported on the flat FTO. In comparison, our IO-FTO (core)-TiO₂ (shell) DSSCs can achieve similar efficiency with three-times less SRF (proportional to dye loading amount) than other devices. We think this striking enhancement is partially due to the effective light trapping/scattering in our IO-FTO DSSCs. The optical properties of this IO-FTO electrode have been previously studied.

On the other hand, we further compare our IO-FTO (core)-TiO₂ (shell) DSSCs with DSSCs using bare TiO₂ inverse opal or coupled with a nanoparticulate TiO₂ layer as photoanodes. By harvesting PhC-induced resonances, these reported structures share similar photonic advantages as in our IO-FTO (core)-TiO₂ (shell) cells. However, when benchmarked with SRF and amount of loaded dye molecules, our IO-FTO (core)-TiO₂ (shell)-based DSSCs exhibit notably enhanced J_{sc} and V_{oc} compared with the reported photonic crystal-structured DSSCs. We assume this enhancement is due to the optimized electron transport in our IO-FTO (core)-TiO₂ (shell) photoanode, which is further investigated by electrochemical impedance spectroscopy (EIS).

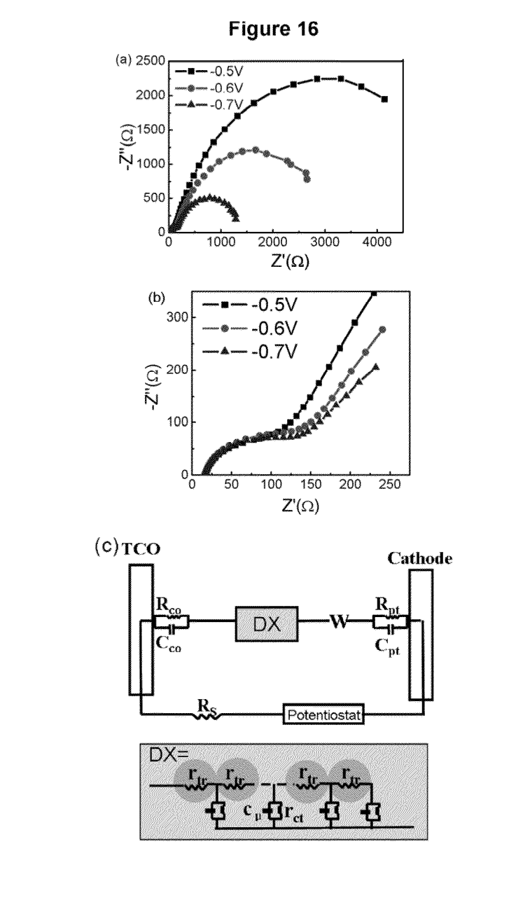

FIG. 16 shows a typical EIS obtained for the same sample shown in the FIG. 15 at forward bias voltage of −0.7V, −0.6V, −0.5V in the dark. The first small arc in the high frequency range of the Nyquist plot, which is magnified in FIG. 16b, is assigned to the electron-transfer process at the Pt-counter/electrolyte interface. Upon decreasing the bias from −0.7V to −0.5V, a short linear impedance feature becomes more evident in the middle frequency range. This is because that the electron concentration in the mesoporous photoanode decreases with reducing forward bias, which leads to the change of electron-transport resistance (Rₜᵣ). In addition, the big arc in low frequency range is assigned to the charge transfer process at the TiO₂/electrolyte interface. With decreasing forward bias from −0.7 V to −0.5 V, the radius of the semicircle increases in the Nyquist plot (see FIG. 16a), indicating a reduction in the interfacial charge recombination rate due to the decrease of electron concentration in the conduction band. As a useful point of reference, conventional nanoparticle TiO₂ DSSCs (i.e., 3% power efficiency based on ˜6 μm) DSSCs have been characterized using EIS. These electronic processes in our IO-FTO (core)-TiO₂ (shell) cells can be described in the FIG. 16c by a geometrically appropriate equivalent circuit, which contains three interfaces formed by TCO|TiO₂, TiO₂|electrolyte and electrolyte|Pt—FTO. The circuit also considers possible communication between the FTO anode with electrolyte as depicted by R_{co} and C_{co}. Rₛ is the sheet resistance of FTO and all resistances out of the cell. Rₚₜ and Cₚₜ are the charge transfer resistance and interfacial capacitance at the platinized-FTO|electrolyte interface, respectively. The diffusion impedance of the redox species in the electrolyte is modeled using a finite W. An extended distributed element (DX) is assigned to represent the interfacial charge separation across a heterogeneous junction in the porous network, in which rₜᵣ is the resistance for electrons transport through each FTO|TiO₂; r_{ct} is the microscopic charge transfer resistance, reflecting the resistance against the charge recombination events from the phase of high (in TiO₂) to the phase of low Fermi levels (in electrolyte); C_{μ} is the chemical capacitance, accounting for the energy storage by virtue of carrier injection, respectively.

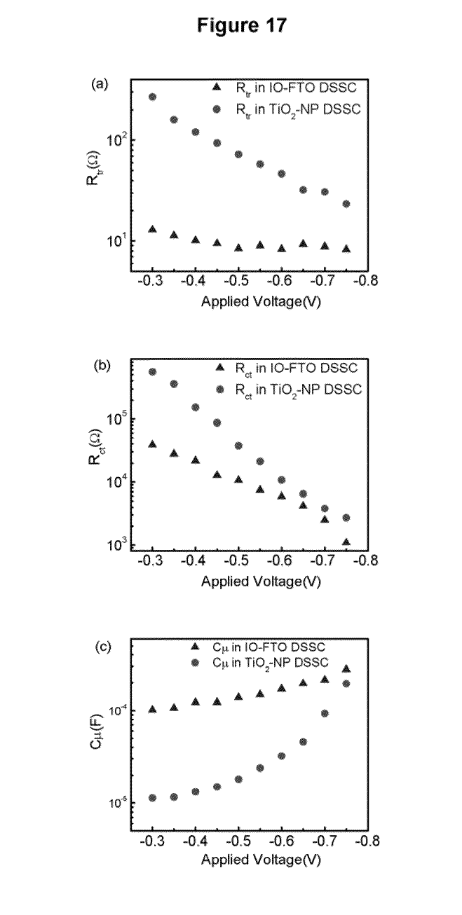

FIG. 17 presents the fitting results of the parameters of cells, including Rₜᵣ(a), R_{ct}(b), C_{μ}(c), measured in dark at different forward biases. It has been reported that the transport resistance, Rₜᵣ, in mesoscopic TiO₂ decreases exponentially with increasing forward bias voltage since it is inversely proportional to the density of electrons. This phenomenon is also observed in our reference TiO₂ nanoparticular DSSC. However, for DSSCs using our IO-FTO (core)-TiO₂ (shell) photoanode, the Rₜᵣ values remains nearly constant when bias voltage varies, as shown in FIG. 17a. The measured Rₜᵣ values at different voltages vary from 8 to 12Ω, nearly two orders of magnitude lower than that of conventional TiO₂ NP-based photoanode, indicating that FTO is a superior material for electron transport. This result suggests that majority of electron transport in our IO-FTO (core)-TiO₂ (shell) PhC photoande occurs in the FTO core region that can undergo drift transport driven by the built-in voltage at FTO—TiO₂ interface, in addition to diffusive transport that dominates the conventional TiO₂ NP-based photoanode.

Charge-transfer resistance, R_{ct}, vs potential is presented in FIG. 17b. In dark, R_{ct} typically exhibits an exponential dependence with bias voltage. It is observed that the value of R_{ct} is much larger than Rₜᵣ, a crucial merit for good performance of DSSCs. We noticed that the R_{ct} in our IO-FTO (core)-TiO₂ (shell) photoanodes is smaller than that in conventional TiO₂ NP DSSC, which leads to a smaller fill factor in our cells in comparison to the conventional TiO₂ DSSCs.

In FIG. 17c, C_{μ} displays a clear exponential dependence with the forward bias, both in our IO-FTO DSSC and the reference TiO₂ NP-DSSC. Since C_{μ} is proportional to the electron density, according to the equation, C_{μ}=e²/kT n, where k is the Boltzmann constant, T is the temperature and e is the electron charge, the increase of the capacitance indicates that good electrical communication is established between the quasi-Fermi level in the semiconductor (TiO₂ shell) and the conducting electron collector (FTO core). However, at a given bias voltage, the C_{μ} values of our IO-FTO (core)-TiO₂ (shell)-based DSSCs is approximately 1 order of magnitude larger for than that of conventional TiO₂ NP-DSSCs. This phenomenon indicates that there is significantly higher electron accumulation in the FTO core of our electrode, which agrees with the higher density of states in FTO than that of TiO₂ (10²⁰ cm⁻³).

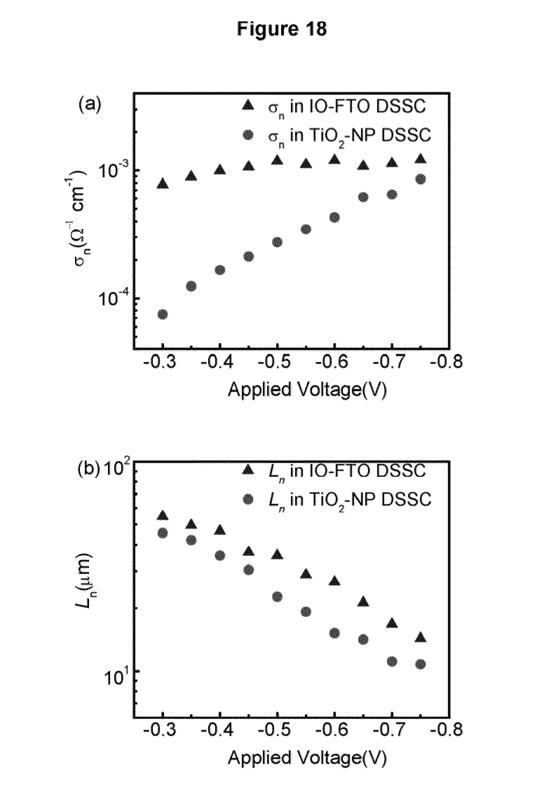

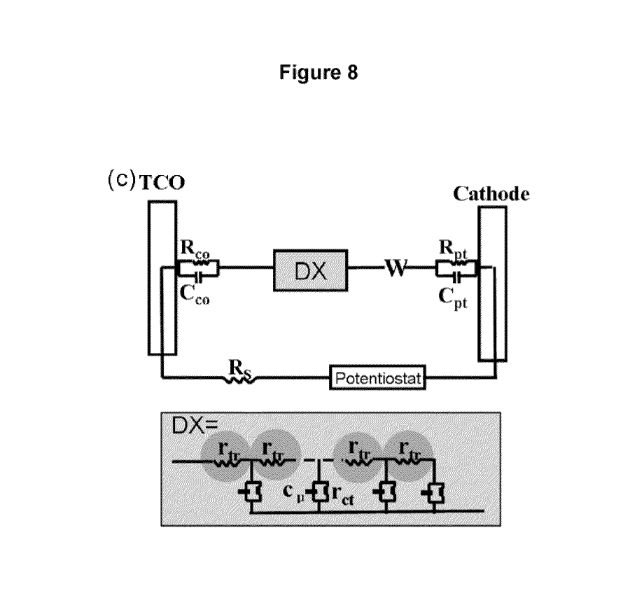

Derived from the EIS measurements, FIG. 18 exhibits the comparison in electron conductivity and effective electron traverse length for both types of devices. The electron conductivity, σₙ, can be derived according to the equation: σₙ=L/BRₜᵣ⁻¹, where Rₜᵣ is the macroscopic transport resistance, L is the thickness of the photoanode, and B is the projected area of the photoanode exposed through the Suryln frame. In FIG. 18a, the conductivities of IO-FTO (triangle) and traditional TiO₂ nanoparticles (circle) based DSSCs are plotted and compared vs the applied forward bias. Compared to the TiO₂ NP cell, our IO-FTO (core)-TiO₂ (shell) photoanodes displays more than 100 times greater conductivity at equal applied potentials, which can be attributed to the better conductivity and integrity of the IO-FTO core as the backbone of the photoelectrodes. This is an important result with respect to photovoltaic performance as it renders the cell tolerance to much faster electron recombination kinetics, especially at the voltage of maximal power.

The competition between the collection and the recombination of electrons can be expressed in terms of the electron diffusion length (Lₙ), according to equation:

$${L}_{n} = \sqrt{\frac{{R}_{ct}}{{R}_{rt}}} .$$

An electron diffusion length much greater than the photoanode film thickness ascertains effective collection of photo-generated charge carriers. As shown in FIG. 18b, the calculated electron diffusion length values, 10˜50 μm depending on the potential, are significantly higher than the thickness of IO-FTO photoanode (˜2 μm), indicating that the electron transport is not the bottleneck of our IO-FTO (core)-TiO₂ (shell) DSSCs. Moreover, the Lₙ in our structure is even better than that in an efficient nanoparticle TiO₂ film. The core-shell structure is quite favorable for electron diffusion because the semiconducting layer of TiO₂ is only a few nanometers. The significant higher carrier mobility in FTO (65 cm²V⁻¹ s⁻¹) than in TiO₂ (10⁻⁶ cm²V⁻¹ s⁻¹) can reallocate transport process from TiO₂ to FTO, and significantly reduce the transport time and prevent the exposure of photoelectrons to counter charges so as to suppress recombination. This is consistent with its higher charge collection yield and higher J_{sc}. Moreover, the interfacial built-in potential of FTO/TiO₂ sweeps the electrons into FTO collector; while in comparison, there is no such effect in the porous TiO₂ NP network.

EIS analysis indicates that our FTO photoanodes with inverse opal structure can provide an easy path for electron transport, resulting in low electron transport resistance Rₜᵣ and long electron diffusion length.

### REFERENCES

1. Yang, Z.; Xu, T.; Gao, S.; Welp, U.; Kwok, K. W., Enhanced Electron Collection in TiO2 Nanoparticle-Based Dye-Sensitized Solar Cells by An Array of Metal Micropillars on A Planar Fluorinated Tin Oxide Anode. J. Phys. Chem. C 2010, 114, 19151-19156.
2. Yang, Z.; Gao, S.; Li, W.; Vlasko-Vlasov, V.; Welp, U.; Kwok, W. K.; Xu, T., Three-Dimensional Photonic Crystal Fluorinated Tin Oxide (FTO) Electrodes: Synthesis, Optic and Electrical Properties. ACS Applied Materials & Interfaces 2011, 3 1101.
3. Grätzel, M., Photoelectrochemical Cells. Nature 2001, 414, 338-344.
4. Hamann, T. W.; Jensen, R. A.; Martinson, A. B. F.; van Ryswyk, H.; Hupp, J. T., Advancing beyond current generation dye-sensitized solar cells. Energy Environ. Sci. 2008, 1, 66-78.
5. Oregan, B.; Gratzel, M., A Low-Cost, High-Efficiency Solar-Cell Based on Dye-Sensitized Colloidal Tio2 Films. Nature 1991, 353, 737-740.
6. Peter, L., “Sticky Electrons” Transport and Interfacial Transfer of Electrons in the Dye-sensitized Solar Cell. Acc. Chem. Res. 2009, 42, 1839-1847.
7. Boschloo, G.; Hagfeldt, A., Characteristics of the Iodide/Triiodide Redox Mediator in Dye-Sensitized Solar Cells. Acc. Chem. Res. 2009, 42, 1819-1826.
8. Papageorgiou, N.; Grätzel, M.; Infelta, P. P., On the relevance of mass transport in thin layer nanocrystalline photoelectrochemical solar cells. Sol. Energy Mater. Sol. Cells 1996, 44, 405-438.
9. Papageorgiou, N.; Barbé, C.; Grätzel, M., Morphology and Adsorbate Dependence of Ionic Transport in Dye Sensitized Mesoporous TiO2 Films. J. Phys. Chem. B 1998, 102, 4156-4164.
10. Junghänel, M.; Tributsch, H., Role of Nanochemical Environments in Porous TiO2 in Photocurrent efficiency and Degradation in Dye sensitized solar cells. J. Phys. Chem. B 2005, 109, 22876-22883.
11. O'Regan, B.; Gratzel, M., A Low-Cost, High-Efficiency Solar-Cell Based on Dye-Sensitized Colloidal Tio2 Films. Nature 1991, 353, 737-740.
12. Hagfeldt, A.; Boschloo, G.; Sun, L.; Kloo, L.; Pettersson, H., Dye-Sensitized Solar Cells. Chem. Rev. 2010, 110, 6595-6663.
13. Peter, L. M., Characterization and modeling of dye-sensitized solar cells. J. Phys. Chem. C 2007, 111, 6601-6612.
14. Frank, A. J.; Kopidakis, N.; van de Lagemaat, J., Electrons in nanostructured TiO2 solar cells: transport, recombination and photovoltaic properties. Coord. Chem. Rev. 2004, 248, 1165-1179.
15. Kopidakis, N.; Park, E. A. S.-G.; van de Lagemaat, J.; Frank, A. J., Ambipolar Diffusion of Photocarriers in Electrolyte-Filled, Nanoporous TiO2. J. Phys. Chem. B 2000, 104, 3930-3936.
16. Kron, G.; Egerter, T.; Werner, J. H.; Rau, U., Electronic Transport in Dye-Sensitized Nanoporous TiO2 Solar Cells Comparision of Electrolyte and Solid-state Devices. J. Phys. Chem. B 2009, 107, 3556-3564.
17. Shockley, W.; Queisser, H. J., Detailed Balance Limit of efficiency of p-n Junction Solar cells. J. Appl. Phys. 1960, 32, 510-519.
18. Tisdale, W. A.; Williams, K. J.; Timp, B. A.; Norris, D. J.; Aydil, E. S.; Zhu, X.-Y., Hot-Electron Transfer from Semiconductor Nanocrystals. Science 2010, 328, 1543-1547.
19. Ross, R. T.; Nozik, A. J., Efficiency of hot carrier solar energy converters. J. Appl. Phys. 1982, 53, 3813-3818.
20. Nazeeruddin, M. K.; De Angelis, F.; Fantacci, S.; Selloni, A.; Viscardi, G.; Liska, P.; Ito, S.; Takeru, B.; Gratzel, M. G., Combined experimental and DFT-TDDFT computational study of photoelectrochemical cell ruthenium sensitizers. J. Am. Chem. Soc. 2005, 127, 16835-16847.
21. Schlichthörl, G.; Park, N. G.; Frank, A. J., Evaluation of the Charge-Collection Efficiency of Dye-Sensitized Nanocrystalline TiO2 Solar Cells. J. Phys. Chem. B 1999, 103, 782-791.
22. Zhu, K.; Neale, N. R.; Miedaner, A.; Frank, A. J., Enhanced charge-collection efficiencies and light scattering in dye-sensitized solar cells using oriented TiO2 nanotubes arrays. Nano Lett. 2007, 7, 69-74.
23. Redmond, G.; Fitzmaurice, D.; Graetzel, M., Effect of surface chelation on the energy of an intraband surface state of a nanocrystalline titania film. J. Phys. Chem. 1993, 97, 6951-6954.
24. Boschloo, G.; Fitzmaurice, D., Spectroelectrochemical Investigation of Surface States in Nanostructured TiO2 Electrodes. J. Phys. Chem. B 1999, 103, 2228-2231.
25. Boschloo, G. K.; Goossens, A., Electron Trapping in Porphyrin-Sensitized Porous Nanocrystalline TiO2 Electrodes. J. Phys. Chem. 1996, 100, 19489-19494.
26. Wang, H.; He, J.; Boschloo, G.; Lindström, H.; Hagfeldt, A.; Lindquist, S.-E., Electrochemical Investigation of Traps in a Nanostructured TiO2 Film. J. Phys. Chem. B 2001, 105, 2529-2533.
27. Chiba, Y.; Islam, A.; Watanabe, Y.; Komiya, R.; Koide, N.; Han, L., Dye-Sensitized Solar Cells with Conversion Efficiency of 11.1%. Jpn. J. Appl. Phs. 2006, 45, L639-L640.
28. Grätzel, M., Solar Energy Conversion by Dye-Sensitized Photovoltaic Cells. Inorg. Chem. 2005, 44, 6841-6851.
29. Bisquert, J.; Zaban, A., The trap-limited diffusivity of electrons in nanoporous semiconductor networks permeated with a conductive phase. Applied Physics A: Materials Science & Processing 2003, 77, 507-514.
30. Hengerer, R.; Kavan, L.; Krtil, P.; Grätzel, M., Orientation Dependence of Charge-Transfer Processes on TiO2 (Anatase) Single Crystals. J. Electrochem. Soc. 2000, 147, 1467-1472.
31. Grimes, C. A., Synthesis and application of highly ordered arrays of TiO2 nanotubes. J. Mater. Chem. 2007, 17, 1451-1457.
32. Mor, G. K.; Shankar, K.; Paulose, M.; Varghese, O. K.; Grimes, C. A., Use of highly-ordered TiO2 nanotube arrays in dye-sensitized solar cells. Nano Lett. 2006, 6, 215-218.
33. Feng, X. S., K.; Varghese, O. K.; Paulose, M.; Latempa, T. J.; Grimes, C. A., Vertically Aligned Single Crystal TiO2 Nanowire Arrays Grown Directly on Transpartent Comducting Oxide Coated Glass: Synthesis Details and Applications. Nano Lett. 2008, 8, 3781-3786.
34. Law, M.; Greene, L. E.; Johnson, J. C.; Saykally, R.; Yang, P. D., Nanowire dye-sensitized solar cells. Nat. Mater. 2005, 4, 455-459.
35. Martinson, A. B. F.; Elam, J. W.; Hupp, J. T.; Pellin, M. J., ZnO nanotube based dye-sensitized solar cells ZnO nanotube based dye-sensitized solar cells. Nano Lett. 2007, 7, 2183-2187.
36. Martinson, A. B. F.; Elam, J. W.; Liu, J.; Pellin, M. J.; Marks, T. J.; Hupp, J. T., Radial electron collection in dye-sensitized solar cells. Nano Lett. 2008, 8, 2862-2866.
37. Mora-Sero, I.; Fabregat-Santiago, F.; Denier, B.; Bisquert, J.; Tena-Zaera, R.; Elias, J.; Levy-Clement, C., Determination of carrier density of ZnO nanowires by electrochemical techniques. Appl. Phys. Lett. 2006, 89, 203117.
38. Shankar, K.; Bandara, J.; Paulose, M.; Wietasch, H.; Varghese, O. K.; Mor, G. K.; LaTempa, T. J.; Thelakkat, M.; Grimes, C. A., Highly Efficient Solar Cells using TiO2 Nanotube Arrays Sensitized with a Donor-Antenna Dye. Nano Lett. 2008, 8, 1654-1659.
39. Kim, D.; Ghicov, A.; Albu, S. P.; Schmuki, P., Bamboo-Type TiO2 Nanotubes: Improved Conversion Efficiency in Dye-Sensitized Solar Cells. J. Am. Chem. Soc. 2008, 130, 16454-16455.
40. Paulose, M.; Shankar, K.; Varghese, O. K.; Mor, G. K.; Grimes, C. A., Application of highly-ordered TiO2 nanotube-arrays in heterojunction dye-sensitized solar cells. J. Phys. D: Appl. Phys. 2006, 39, 2498-2503.
41. Liu, B.; Aydil, E. S., Growth of Oriented Single-Crystalline Rutile TiO2 Nanorods on Transparent Conducting Substrates for Dye-Sensitized Solar Cells. J. Am. Chem. Soc. 2009, 131, 3985-3990.
42. Shankar, K.; Basham, J. I.; Allam, N. K.; Varghese, O. K.; Mor, G. K.; Feng, X.; Paulose, M.; Seabold, J.; Choi, K.-S.; Grimes, C. A., Recent Advances in the Use of TiO2 Nanotube and Nanowire Arrays for Oxidative Photoelectrochemistry J. Phys. Chem. C 2009, 113, 6327-6359.
43. Martinson, A. B. F.; Goes, M. S.; Fabregat-Santiago, F.; Bisquert, J.; Pellin, M. J.; Hupp, J. T., Electron Transport in Dye-Sensitized Solar Cells Based on ZnO Nanotubes: Evidence for Highly Efficient Charge Collection and Exceptionally Rapid Dynamics. J. Phys. Chem. A 2009, 113, 4015-4021.
44. Jennings, J. R.; Ghicov, A.; Peter, L. M.; Schmuki, P.; B., W. A., Dye-Sensitized Solar Cells Based on Oriented TiO2 Nanotube Arrays: Transport, Trapping, and Transfer of Electrons. J. Am. Chem. Soc. 2008, 130, 13364-13372.
45. Martinson, A. B. F.; McGarrah, J. E.; Parpia, M. O. K.; Hupp, J. T., Dynamics of charge transport and recombination in ZnO nanorod array dye-sensitized solar cells. Phys. Chem. Chem. Phys. 2006, 8, 4655-4659.
46. Martinson, A. B. F.; Hamann, T. W.; Pellin, M. J.; Hupp, J. T., New architectures for dye-senstized solar cells. Chem.-Eur. J. 2008, 14, 4458-4467.
47. Asano, T.; Kubo, T.; Nishikitani, Y., Short-Circuit current Density Behavior of Dye-Sensitized Solar Cells. Jpn. J. Appl. Phys. 2005, 44, 6776-6780.
48. Chen, H. H.; Du Pasquier, A.; Saraf, G.; Zhong, J.; Lu, Y., Dye-sensitized solar cells using ZnO nanotips and Ga-doped ZnO films. Semiconductor Science and Technology 2008, 23, 6.
49. Clifford, J. N.; Palomares, E.; Nazeeruddin, M. K.; Grätzel, M.; J. R. Durrant, J. R., Dye Dependent Regeneration Dynamics in Dye Sensitized Nanocrystalline Solar Cells: Evidence for the Formation of a Ruthenium Bipyridyl Cation/Iodide Intermediate. J. Phys. Chem. C 2007, 111, 6561-6567.
50. Gregg, B. A.; Pichot, F.; Ferrere, S.; Fields, C. L., Interfacial Recombination Processes in Dye-Sensitized Solar Cells and Methodes To Passivate the Interfaces. J. Phys. Chem. B 2001, 105, 1422-1429.
51. Ito, S.; Zakeeruddin, S. M.; Comte, P.; Liska, P.; Kuang, D.; Grätzel, M., Bifacial dye-sensitized solar cells based on an ionic liquid electrolyte. Nature Photonics 2008, 2, 693-698.
52. Kang, M. G.; Ryu, K. W.; Chang, S. H.; Park, N. G.; Hong, J. S.; Kim, K.-J., Dependence of TiO2 Film Thickness on Photocurrent-Voltage Characteristics of Dye-Sensitized Solar Cells. Bull. Korean Chem. Soc. 2004, 25, 742-744.
53. O'Regan, B. C.; Lopez-Duarte, I.; Martinez-Diaz, M. V.; Forneli, A.; Albero, J.; Morandeira, A.; Palomares, E.; Torres, T.; Durrant, J. R., Catalysis of Recombination and Its Limitation on Open Circuit Voltage for Dye Sensitized Photovoltaic Cells Using Phthalocyanine Dyes. J. Am. Chem. Soc. 2008, 130, 2906-2907.
54. Splan, K. E.; Massari, A. M.; Hupp, J. T., A Porous Multilayer Dye-Based Photoelectrochemical Cell That Unexpectedly Runs in Reverse. J. Phys. Chem. B 2004, 108, 4111-4115.
55. Paulose, M.; Prakasam, H. E.; Varghese, O. K.; Lily Peng, L.; Popat, K. C.; Mor, G. K.; Tejal A. Desai, T. A.; Grimes, C. A., TiO2 Nanotube Arrays of 1000 μm Length by Anodization of Titanium Foil: Phenol Red Diffusion. J. Phys. Chem. C 2007, 111, 14992-14997.
56. Hoffmann, M. R.; Martin, S. T.; Choi, W. Y.; Bahnemann, D. W., Environmental Applications of Semiconductor Photocatalysis. Chem. Rev. 1995, 95, 69-96.
57. Linsebigler, A. L.; Lu, G. Q.; Yates, J. T., Photocatalysis on TiO₂ Surfaces—Principles, Mechanisms, and Selected Results. Chem. Rev. 1995, 95, 735-758.
58. Thompson, T. L.; Yates, J. T., Surface science studies of the photoactivation of TiO₂—new photochemical processes. Chem. ReV. 2006, 106, 4428-4453.
59. Alvaro, M.; Aprile, C.; Benitez, M.; Carbonell, E.; Garcia, H., Photocatalytic activity of structured mesoporous TiO₂ materials. J. Phys. Chem. B 2006, 110, 6661-6665.
60. He, D. P.; Lin, F. R., Preparation and photocatalytic activity of anatase TiO₂ nanocrystallites with high thermal stability. Mater. Lett. 2007, 61, 3385-3387.
61. Finazzi, E.; Di Valentin, C.; Pacchioni, G., Boron-Doped Anatase TiO2: Pure and Hybrid DFT Calculations. J. Phys. Chem. C 2009, 113, 220-228.
62. Gopal, N. O.; Lo, H. H.; Ke, S. C., Chemical state and environment of boron dopant in B,N-codoped anatase TiO2 nanoparticles: An avenue for probing diamagnetic dopants in TiO2 by electron paramagnetic resonance spectroscopy. J. Am. Chem. Soc. 2008, 130, 2760.
63. Periyat, P. P., S. C.; McCormack, D. E.; Colreavy, J.; Hinder, S. J., Improved High-Temperature Stability and Sun-Light-Driven Photocatalytic Activity of Sulfur-Doped Anatase TiO2. J. Phys. Chem. C 2008, 112, 7644-7652.
64. Periyat, P. M., D. E.; Hinder, S. J.; Pillai, S. C., One-Pot Synthesis of Anionic (Nitrogen) and Cationic (Sulfur) Codoped High-Temperature Stable, Visible Light Active, Anatase Photocatalysts. J. Phys. Chem. C 2009, 113, 3246-3253.
65. Asahi, R.; Morikawa, T.; Ohwaki, T.; Aoki, K.; Taga, Y., Visible-Light Photocatalysis in Nitrogen-Doped Titanium Oxides. Science 2001, 293, 269.
66. Zuo, F.; Wang, L.; Wu, T.; Zhang, Z.; Borchardt, D.; Feng, P., Self-Doped Ti³⁺ Enhanced Photocatalyst for Hydrogen Production under Visible Light. J. Am. Chem. Soc. 2010, 132, 11856-11857.
67. Chen, X.; Liu, L.; Yu, P. Y.; Mao, S. S., Increasing Solar Absorption for Photocatalysis with Black Hydrogenated Titanium Dioxide Nanocrystals. Science 2011, 331, 746-750.
68. Justicia, I.; Ordejon, P.; Canto, G.; Mozos, J. L.; Fraxedes, J.; Battiston, G. A.; Gerbasi, R.; Figueras, A., Designed self-doped titanium oxide thin films for efficient visible light photocatalysis. AdV. Mater. 2002, 14, 1399-1402.
69. Nowotny, J.; Bak, T.; Nowotny, M. K.; Sheppard, L. R., TiO2 Surface Active Sites for Water Splitting. J. Phys. Chem. B 2006, 110, 18492-18495.
70. Cronemeyer, D. C., Infrared Absorption of Reduced Rutile TiO2 Single Crystals. Phys. ReV. 1959, 113, 1222-1226.
71. Teleki, A.; Pratsinis, S. E., Blue nano titania made in diffusion flames. Phys. Chem. Chem. Phys. 2009, 11, 3742-3747.
72. Komaguchi, K.; Maruoka, T.; Nakano, H.; Imae, I.; Ooyama, Y.; Harima, Y., Electron-Transfer Reaction of Oxygen Species on TiO2 Nanoparticles Induced by Sub-band-gap Illumination. J. Phys. Chem. C 2010, 114, 1240-1245.
73. Xu, T.; Peterson, I. R.; Lakshmikantham, M.; Metzger, R. M., Rectification by a monolayer of Hexadecylquinolinium tricyanoquinodimethanide between gold electrodes. Angew. Chem. Int. Ed. 2001, 40, 1749-1752.
74. Metzger, R. M.; Xu, T.; Peterson, I. R., Electrical Rectification by A Monolayer of Hexadecylquinolinium Tricyanoquinodimethanide Measured between Macroscopic Gold Electrodes. J. Phys. Chem. B 2001, 105, 7280-7290.
75. Xu, T.; Morris, T.; Szulczewski, G.; Amaresh, R.; Gao, Y.; Street, S. C.; L., K.; Metzger, R. M. A., Spectroscopic Study of Hexadecylquinolinium Tricyanoquinodimethanide as a Monolayer and in Bulk. J. Phys. Chem. B 2002, 106, 10374-10381.
76. Xu, T.; Morris, T.; Szulczewski, G. J.; Metzger, R. M., Current-Voltage Characteristics of an LB Monolayer of di-Decylammonium Tricyanoquinodimethanide Measured between Macroscopic Gold Electrodes. J. Mater. Chem. 2002, 12, 3167-3171.
77. Gao, Y.; Konovalova, T.; Xu, T.; Kispert, L., Electron Transfer of Carotenoides imbedded in MCM-41 and Ti-MCM-41: EPR, ENDOR and UV/Vis studies. J. Phys. Chem. B 2002, 106, 10808-10815.
78. Patel, U.; Xiao, Z. L.; Hua, J.; Xu, T.; Rosenmann, D.; Novosad, V.; Pearson, J.; Welp, U.; Kwok, W. K.; Crabtree, G. W., Origin of the matching effect in a superconducting film with a hole array. Phys. Rev. B 2007, 76, 020508.
79. Xu, T.; Zach, M. P.; Xiao, Z. L.; Rosenmann, D.; Welp, U.; Kwok, W. K.; Crabtree, G. W., Self-assembled monolayer enhanced hydrogen sensing with ultra-thin palladium films. Appl. Phys. Lett. 2005, 86, 203104.

80. Xu, T.; Zangari, G.; Metzger, R. M., Periodic Holes with 10 nm Diameter Produced by Grazing Ar+ Milling of the Barrier Layer in Hexagonally Ordered Nanoporous Alumina. Nano Lett. 2002, 2, 37-41.
81. Xu, T.; M., M. R., Nanoditches Fabricated using a Carbon Nanotube as a Contact Mask. Nano Lett. 2002, 2, 1061-1064.
82. Lin, C.; Xu, T.; Yu, J.; Ge, Q.; Xiao, Z., Hydrogen Spillover Enhanced Hydriding Kinetics of Palladium-Doped Lithium Nitride to Lithium Imide. J. Phys. Chem. C 2009, 113, 8513-8517.
83. Xu, T.; Lin, C.; Wang, C.; Brewe, D. L.; Ito, Y.; Lu, J., Synthesis of Supported Platinum Nanoparticles from Li—Pt Solid Solution. J. Am. Chem. Soc. 2010, 132, 2151-2153.
84. Kulchytskyy, I.; Kocanda, M. G.; Xu, T., Direct mass determination of hydrogen uptake using a quartz crystal microbalance. Appl. Phys. Lett. 2007, 91, 113507-3.
85. Chakrabarti, A.; Xu, T.; Paulson, L. K.; Krise, K. J.; Maguire, J. A.; S., H. N., Synthesis of Boron Nanorods by Smelting Non-toxic Boron Oxide in Liquid Lithium. J. Nanomaterials 2010, 2010, Article ID 589372.
86. Yang, Z.; Xu, T.; Y., I.; Welp, U.; Kwok, W. K., Enhanced Electron Transport in Dye-Sensitized Solar Cells Using Short ZnO Nanotips on A Rough Metal Anode. J. Phys. Chem. C 2009, 113, 20521-20526.
87. Xu, P.; Lu, J.; Xu, T.; Gao, S.; Huang, B.; Dai, Y., I2-Hydrosol-Seeded Growth of (I2)n-C-Codoped Meso/Nanoporous TiO2 for Visible Light-Driven Photocatalysis. J. Phys. Chem. C 2010, 114, 9510-9517.
88. Xu, P.; Xu, T.; Lu, J.; Gao, S.; Hosmane, N. S.; Huang, B.; Dai, Y.; Wang, Y., Visible light-driven photocatalytic S- and C-codoped meso/nanoporous TiO2. Energy Environ. Sci. 2010, DOI 10.1039/c001940m.
89. O'Regan, B. C.; Bakker, K.; Kroeze, J.; Smit, H.; Sommeling, P.; Durrant, J. R., Measuring Charge Transport from Transient Photovoltage Rise Time. A New Tool To Investigate Electron Transport in Nanoparticle Films. J. Phys. Chem. B 2006, 110, 17155-17160.
90. Adachi, M.; Sakamoto, M.; Jiu, J. T.; Ogata, Y.; Isoda, S., Determination of parameters of electron transport in dye-sensitized solar cells using electrochemical impedance spectroscopy. J. Phys. Chem. B 2006, 110, 13872-13880.
91. van de Lagemaat, J.; Park, N.-G.; Frank, A. J., Influence of Electrical Potential distribution, Charge Transport, and Recombination on the Photopotential and Photocurrent Conversion Efficiency of Dye-Sensitized Nanocrystalline TiO2 Solar Cells: A Study by Electrical Impedance and Optical Modulation Techniques. J. Phys. Chem. B 2000, 104, 2044-2052.
92. Bisquert, J., Theory of the Impedance of Electron Diffuison and Recombination in a Thin Layer. J. Phys. Chem. B 2002, 106, 325-333.
93. Schwarzburg, K.; Willig, F., Origin of Photovoltage and Photocurrent in the Nanoporous Dye-Sensitized Electrochemical Solar Cell. J. Phys. Chem. B, 1999, 103, 5743-5746.
94. Juan Bisquert, J.; Garcia-Belmonte, G.; Fabregat-Santiago, F., Modeling the electric potential distribution in the dark in nanoporous semiconductor electrodes. J Solid State Electrochem. 1999, 3, 337-347.
95. Jiang, C. Y.; Sun, X. W.; Lo, G. Q.; Kwong, D. L.; Wang, J. X., Improved dye-sensitized solar cells with a ZnO-nanoflower photoanode. Applied Physics Letters 2007, 90, 3.
96. Cheng, H. M.; Chiu, W. H.; Lee, C. H.; Tsai, S. Y.; Hsieh, W. F., Formation of Branched ZnO Nanowires from Solvothermal Method and Dye-Sensitized Solar Cells Applications. J. Phys. Chem. C 2008, 112, 16359-16364.
97. Xia, J.; Masaki, N.; Jiang, K.; Yanagida, S., Deposition of a Thin Film of TiOx from a Titanium Metal Target as Novel Blocking Layers at Conducting Glass/TiO2 Interfaces in Ionic Liquid Mesoscopic TiO2 Dye-Sensitized Solar Cells†. J. Phys. Chem. B 2006, 110, 25222-25228.
98. Hamal, D. B.; Klabunde, K. J., Synthesis, characterization, and visible light activity of new nanoparticle photocatalysts based on silver, carbon, and sulfur-doped TiO₂ J. Colloid Inter. Sci. 2007, 311, 514-522.
99. Hahn, R.; Schmidt-Stein, F.; Salonen, J.; Thiemann, S.; Song, Y.; Kunze, J.; Lehto, V.; Schmuki, P., Semimetallic TiO₂ Nanotubes. Angew. Chem. Int. Ed. 2009, 48, 7236-7239.
100. Kavan, L.; Grätzel, M.; Gilbert, S. E.; Klemenz, C.; Schell, H. J., Electrochemical and Photoelectrochemical Investigation of Single-Crystal Anatase. J. Am. Chem. Soc. 1996, 118, 6716-6723.
101. Forro, L.; Chauvet, O.; Emin, D.; Zuppiroli, L.; Berger, H.; Lévy, F., High mobility n□type charge carriers in large single crystals of anatase (TiO2). J. Appl. Phys. 1994, 75, 633.
102. Wagner, P.; Helbig, R., Hall effect and anisotropy of the mobility of the electrons in zinc oxide. J. Phys. Chem. Sol. 1974, 35.
103. Wang, A.; Babcock, J. R.; Edleman, N. L.; Metz, A. W.; Lane, M. A.; Asahi, R.; Dravid, V. P.; Kannewurf, C. R.; Freeman, A. J.; Marks, T. J., Indium-cadmium-oxide films having exceptional electrical conductivity and optical transparency:Clues for optimizing transparent conductors. Proc. Natl. Acad. Sci. 2001, 98, 7113-7116.
104. Green, A. N. M.; Palomares, E.; Haque, S. A.; Kroon, J. M.; Durrant, J. R., Charge Transport versus Recombination in Dye-Sensitized Solar Cells Employing Nanocrystalline TiO2 and SnO2 Films. J. Phys. Chem. B 2005, 109, 12525-12533.
105. Peter, L. M., Dye-sensitized nanocrystalline solar cells. Phys. Chem. Chem. Phys 2007, 9, 2630-2642.
106. Snaith, H. J.; Schmidt-Mende, L.; Grätzel, M., Light intersity, temperature, and thickness dependance of the open-circuit voltage in solid-state dye-sensitized solar cells. Phys. Rev. B 2006, 74, 045306.
107. Ito, S.; Ha, N. L. C.; Rothenberger, G.; Liska, P.; Comte, P.; Zakeeruddin, S. M.; Pechy, P.; Nazeeruddin, M. K.; Gratzel, M., High-efficiency (7.2%) flexible dye-sensitized solar cells with Ti-metal substrate for nanocrystalline-TiO2 photoanode. Chem. Commun. 2006, 4004-4006.
108. Chen, H.-Y.; Hou, J.; Zhang, S.; Liang, Y.; Yang, G.; Yang, Y.; Yu, L.; Wu, Y.; Li, G., Polymer solar cells with enhanced open-circuit voltage and efficiency. Nature Photonics 2009, 3, 649-653.
109. Calnan, S.; Tiwari, A. N., High mobility transparent conducting oxides for thin film solar cells. Thin Solid Films 2010, 518, 1839-1849.
110. Aduda, B. O.; Ravirajan, P.; Choy, K. L.; Nelson, J., Effect of morphology on electron drift mobility in porous TiO2. Internatl. J. Photoenergy 06, 141-147.
111. Richter, C.; Schmuttenaer, C. A., Exciton-like trap states limit electron mobility in TiO2 nanotubes. Nature Nanotech. 2010, 5, 769-772.
112. Forro, L.; Chauvet, O.; Emin, D.; Zuppiroli, L.; Berger, H.; Lévy, F., High mobility n-type charge carriers in large single crystals of anatase (TiO2). J. Appl. Phys. 1994, 75, 633-635.
113. Rühle, S.; Dittrich, T., Investigation of the Electric Field in TiO2/FTO Junctions Used in Dye-Sensitized Solar Cells by Photocurrent Transients. J. Phys. Chem. B 2005, 109, 9522-9526.
114. Zhong, Y. L.; Midya, A.; Ng, Z.; Chen, Z.-K.; Daenen, M.; Nesladek, M.; Loh, K. P., Diamond-Based Molecular Platform for Photoelectrochemistry, J. Am. Chem. Soc. 2008, 130, 17218-17219.
115. Benda, V.; Gower, J.; Grant, D. A., Power Semiconductor De Vices: Theory and Applications; John Wiley & Sons Ltd.: Chichester, U.K. 1999, pp 62-65.
116. Helander, M. G.; Wang, Z. B.; Qiu, J.; Lu, Z. H., Band alignment at metal/organic and metal/oxide/organic interfaces. Appl. Phys. Lett. 2008, 93, 193310.
117. George, S. M., Atomic Layer Deposition: An Overview. Chem. Rev. 2010, 110, 111-131.
118. Breen, T. L.; Fryer, P. M.; Nunes, R. W.; Rothwell, M. E., Patterning Indium Tin Oxide and Indium Zinc Oxide Using Microcontact Printing and Wet Etching. Langmuir 2002 18, 194-197.
119. Emons, T. T.; Li, J.; Nazar, L. F., Synthesis and Characterization of Mesoporous Indium Tin Oxide Possessing an Electronically Conductive Framework. J. AM. CHEM. SOC. 2002, 124, 8516-8517.
120. Mahajeri, M.; Voigt, M.; Klupp Taylor, R. N.; Reindl, A.; Peukert, W., Evaluation of the film formation and the charge transport mechanism of indium tin oxide nanoparticle films. Thin Solid Films 2010, 518, 3373-3381.
121. Lee, I.; S.-Y., L., Growth of Conductive Indium Tin Oxide (ITO) Nanoparticles by Mineralization in Ring-Shaped Biomimetic Templates. J. Phys. Chem. C 2009, 113, 17372-17377.
122. Purwanto, A.; Widiyandari, H.; Hidayat, D.; Iskandar, F.; Okuyama, K., Facile Method for the Fabrication of Vertically Aligned ITO Nanopillars with Excellent Properties. Chem. Mater. 2009, 21, 4087-4089.
123. Choi, S.-I.; Nam, K. M.; Park, B. K.; Seo, W. S.; Park, J. T., Preparation and Optical Properties of Colloidal, Monodisperse, and Highly Crystalline ITO Nanoparticles. Chem. Mater. 2008, 20, 2609-2611.
124. Aouaj, M. A.; Diaz, R.; Belayachi, A.; Rueda, F.; Abd-Lefdil, M., Comparative study of ITO and FTO thin films grown by spray pyrolysis. Mater. Res. Bull. 2009, 44 1458-1461.
125. Epifani, M.; Di'az, R.; Arbiol, J.; Siciliano, P.; Morante, J. R., Solution Synthesis of Thin Films in the SnO2-In2O3 System: A Case Study of the Mixing of Sol-Gel and Metal-Organic SolutionProcesses. Chem. Mater. 2006, 18, 840-846.
126. Cho, Y.-S.; Yi, G.-R.; J.-J., H.; S.-H., J.; S.-M., Y., Colloidal indium tin oxide nanoparticles for transparent and conductive films. Thin Solid Films 2006, 515, 1864-1871.
127. Hwang, I.; McNeill, C. R.; Greenhama, N. C., Drift-diffusion modeling of photocurrent transients in bulk heterojunction solar cells. J. Appl. Phys. 2009, 106, 094506.
128. Chen, P.; Yum, J. H.; De Angelis, F.; Mosconi, E.; Fantacci, S.; Moon, S.-J.; Baker, R. H.; Ko, J.; Nazeeruddin, M. K.; Grätzel, M., High Open-Circuit Voltage Solid-State Dye-Sensitized Solar Cells with Organic Dye. Nano Lett. 2009, 9, 2487-2492.
129. Pandeya, S. S.; Sakaguchia, S.; Yoshihiro, Y.; Hayasea, S., Influence of nature of surface dipoles on observed photovoltage in dye-sensitized solar cells as probed by surface potential measurement. Organic Electronics 2010, 11, 419-426.
130. Hamann, T. W.; Farha, O. K.; Hupp, J. T., Outer-Sphere Redox Couples as Shuttles in Dye-Sensitized Solar Cells. Performance Enhancement Based on photoelectrode Modification via Atomic Layer Deposition. J. Phys. Chem. C 2008, 112, 19756-19764.
131. Kuciauskas, D.; Freund, M. S.; Gray, H. B.; Winkler, J. R.; Lewis, N. S., Electron Transfer Dynamics in Nanocrystalline Titanium Dioxide Solar Cells Sensitized with Ruthenium or Osmium polypyridyl Complexes. J. Phys. Chem. B 2001, 105, 392-403.
132. Hamann, T. W.; Farha, O., K.; Hupp, J. T., Outer-Sphere Redox Couples as Shuttles in Dye-Sensitized Solar Cells. Performance Enhancement Based on Photoelectrode Modification via Atomic Layer Deposition. J. Phys. Chem. C 2008, 112, 19756-19764.
133. Fabregat-Santiago, F.; Bisquert, J.; Cevey, L.; Chen, P.; Wang, M.; Zakeeruddin, S. M.; Grätzel, M., Electron Transport and Recombination in Solid-State Dye solar Cell with Spiro-OmeTAD as Hole Conductor. J. Am. Chem. Soc. 2009, 131, 558-562.
134. Ding, I.-K.; Tétreault, N.; Brillet, J.; Hardin, B. E.; Smith, E. H.; Rosenthal, S. J.; Sauvage, F.; Grätzel, M.; McGehee, M. D., Pore-Filling of Spiro-OMeTAD in Solid-State Dye Sensitized Solar Cells: Quantification, Mechanism, and Consequences for Device Performance. Adv. Funct. Mater. 2009, 19, 1-6.
135. Li, T. C.; Spokoyny, A. M.; She, C.; Farha, O. K.; Mirkin, C. A.; Marks, T. J.; Hupp, J. T., Ni(III)/(IV) Bis(dicarbollide) as a Fast, Noncorrosive Redox Shuttle for Dye-Sensitized Solar Cells. J. Am. Chem. Soc. 2010, 132, 4580-4582.
136. Wang, M.; Chamberland, N.; Breau, L.; Moser, J.-E.; Humphry-Baker, R.; Marsan, B.; Zakeeruddin, S. M.; Grätzel, M., An organic redox electrolyte to rival triiodide/iodide in dye-sensitized solar cells. Nature Chemistry 2010, 2, 385-389.
137. Usami, A., Theoretical Study of Application of Multiple Scattering of Light to a Dye-Sensitized Nanocrystalline Photoelectrochemical Cell. Chem. Phys. Lett. 1997, 277, 105-108.
138. Nishimura, S.; Abrams, N.; Lewis, B. A.; Halaoui, L. I.; Mallouk, T. E.; Benkstein, K. D.; van de Lagemaat, J.; Frank, A. J., Standing Wave Enhancement of Red Absorbance and Photocurrent in Dye-Sensitized Titanium Dioxide Photoelectrodes Coupled to Photonic Crystals. J. Am. Chem. Soc. 2003, 125, 6306-6310.
139. Mihi, A.; Miguez, H., Origin of Light-Harvesting Enhancement in Colloidal-Photonic-Crystal-Based Dye-Sensitized Solar Cells. J. Phys. Chem. B 2005, 109, 15968-15976.
140. Mihi, A.; Lopez-Alcaraz, F. J.; Miguez, H., Full Spectrum Enhancement of the Light Harvesting Efficiency of Dye Sensitized Solar Cells by Including Colloidal Photonic Crystal Multilayers. Appl. Phys. Lett. 2006, 88, 193110.
141. Mihi, A.; Calvo, M. E.; Anta, J. A.; Miguez, H., Spectral Response of Opal-Based Dye-Sensitized Solar Cells. J. Phys. Chem. C 2008, 112, 13-17.
142. Nishimura, S.; Abrams, N.; Lewis, B. A.; Halaoui, L. I.; Mallouk, T. E.; Benkstein, K. D.; van de Lagemaat, J.; Frank, A. J., Standing wave enhancement of red absorbance and photocurrent in dye-sensitized titanium dioxide photoelectrodes coupled to photonic crystals. J. Am. Chem. Soc. 2003, 125, 6306-6310.
143. Waterhouse, G. I. N.; Metson, J. B.; Idriss, H.; Sun-Waterhouse, D., Physical and optical properties of inverse opal CeO2 photonic crystals. Chem. Mater 2008, 20, 1183-1190.
144. Turner, M. E.; Trentler, T. J.; Colvin, V. L., Thin Films of Macroporous Metal Oxides. Adv. Mater. 2001, 13, 180-183.
145. Jiang, P.; Bertone, J. F.; Colvin, V. L., A lost-was approach to mondisperse colloids and their crystals. Science 2001, 291, 453-457.
146. Jiang, P.; Ostojic, G. N.; Narat, R.; Mittleman, D. M.; Colvin, V. L., The fabrication and bandgap engineering of photonic multilayers. Adv. Mater. 2001, 13, 389-393.
147. Jiang, P.; Larrabee, D. C.; Colvin, V. L.; Mittleman, D. M., Colloidal photonic superlattices. Phys. Rev. B 2001, 64, 205103.
148. Holland, B. T.; Blanford, C. F.; Stein, A., Synthesis of Macroporous minerals with highly ordered three-dimensional arrays of spheroidal voids. Science 1998, 281, 538-540.
149. Yan, H.; Blanford, C. F.; Holland, B. T.; Smyrl, W. H.; Stein, A., General synthesis of periodic macroporous solids by templated salt precipitation and chemical conversion. Chem. Mater. 2000, 12, 1134-1141.
150. Schroden, R. C.; Al-Daous, M.; Stein, A., Self-Modification of Spontaneous Emission by Inverse Opal Silica Photonic Crystals. Chem. Mater 2001, 13, 2945-2950.
151. Yablonovitch, E., Inhibited Spontaneous Emission in Solid-State Physics and Electronics. Phys. Rev. Lett. 1987, 58, 2059-2062.
152. John, S., Strong Localization of Photons in Certain Disordered Dielectric Superlattices. Phys. Rev. Lett. 1987, 58, 2486-2489.
153. Han, C.-H.; Han, S. D.; Gwak, J.; Khatkar, S. P., Synthesis of indium tin oxide (ITO) and fluorine-doped tin oxide (FTO) nano-powder by sol-gel combustion hybrid method. Mater. Lett. 2007 61, 1701-1703.
154. Ito, S.; Liska, P.; Comte, P.; Charvet, R.; Péchy, P.; Bach, U.; Schmidt-Mende, L.; Zakeeruddin, S. M.; Kay, A.; Nazeeruddin, M. K.; Grätzel, M., Control of dark current in photoelectrochemical (TiO2/I-I3-) and dye-sensitized solar cells. Chem. Commun. 2005, 4351.
155. Hatton, B.; Mishchenko, L.; Davis, S.; Sandhage, K. H.; Aizenberg, J., Assembly of large-area, highly ordered, crack-free inverse opal films. Proc. Natl. Acad. Sci. 2010, 107, 10354-10359.
156. Tao, C.; Zu, W.; An, Q.; Li, G., Theoretical Demonstration of Efficientcy Enhancement of Dy-Sensitized Slolar Cells with Double-Inverse Opal as Mirrorss. J. Phys. Chem. C 2010, 114, 10641-10647.
157. Li, G.; Tao, C., Personal Communication with authors of JPC-C 2010, 114, 10641-10647. In The authors of the paper indicates that lower dielectric constant of the inverse opal materials leads to greater cell efficiency according to Equation 15. ed.; 2010.
158. Izumi, Y.; Okamoto, S.; Takizawa, K.; Tanaka, K., Improving the Light Out-Coupling Properties of Inorganic Thin-Film Electroluminescent Devices. Jpn. J. Appl. Phys. 2002 41, 1284-1287.
159. Christ, A.; Tikhodeev, S. G.; Gippius, N. A.; Kuhl, J.; Giessen, H., Waveguide-Plasmon Polaritons: Strong Coupling of Photonic and Electronic Resonances in a Metallic Photonic Crystal Slab. Phys. Rev. Lett. 2003, 91, 183901.
160. Lee, J.; Choi, J.; Lee, J.; Choi, S. K.; Chun, H. D., Electrostatic capacitance of TiO2 nanowires in a porous alumina template. Nanotechnology 2005, 16, 1449-1453.
161. Park, Y. R.; Kim, K. J., Structural and optical properties of rutile and anatase TiO2 thin films: Effects of Co doping. Thin Solid Films 2005, 484, 34-38.
162. STAMATE, M.; LAZAR, G.; LAZAR, I., ANATASE—RUTIL TiO2 THIN FILMS DEPOSITED IN A D.C. MAGNETRON SPUTTERING SYSTEM. Rom. J. Phys., 2008, 53, 217-221.
163. Tennakone, K.; Kottegoda, I. R. M.; De Silva, L. A. A.; Perera, V. P. S., The possibility of ballistic electron transport in dye-sensitized semiconductor nanocrystalline particle aggregates. Semicond. Sci. Technol. 1999, 14, 975-978.
164. Niinobe, D.; Makari, Y.; Kitamura, T.; Wada, Y.; Yanagida, S., Origin of Enhancement in Open-Circuit Voltage By Adding ZnO to Nanocrystalline SnO2 in Dye-Sensitized Solar Cells. J. Phys. Chem. 8 2005, 109, 17892-17900.
165. Kay, A.; Gratzel, M., Dye-sensitized core-shell nanocrystals: Improved efficiency of mesoporous tin oxide electrodes coated with a thin layer of an insulating oxide. Chem. Mater. 2002, 14, 2930-2935.
166. Benkoe, G.; Kallioinen, J.; Myllyperkioe, P.; Trif, F.; Korppi-Timmola, J. E. I.; Yartsev, A. P.; Sundstroem, V., Interligand Electron Transfer Determines Triplet Excited State Electron Injection in RuN3-Sensitized TiO2 films. J. Phys. Chem. 8 2004, 108, 2862-2867.
167. Kallioinen, J.; Benkoe, G.; Sundstroem, V.; Korppi-Tommola, J. E. I.; Yartsev, A. P., Electron Transfer from the Singlet and Triplet Excited States of Ru(dcbpy)2 (NCS)2 into Nanocrystalline TiO2 Thin films. J. Phys. Chem. 8 2002, 106, 4396-4404.
168. Asbury, J. B.; Ellingson, R. J.; Ghosh, H. N.; Ferrere, S.; Nozik, A. J.; Lian, T., Femtosecond IR Study of Excited-State Relaxation and Electron-Injection Dynamics of Ru(dcbpy)2(NCS)2 in Solution and on Nanocrystalline TiO2 and Al2O3 Thin Films. J. Phys. Chem. B 1999, 103, 3110-3119.
169. Supriyo Datta, C. H. A., Alec Broers, Michael Pepper, Electronic Transport in Mesoscopic Systems. Cambridge University Press: New York, 1997; p 57-111.
170. Anderson, K.; Fleshman, W. S., Reactivity of Titanium Hydride with Air. Ind. Eng. Chem. 1950, 42, 1381-1383.
171. Papageorgiou, N.; Grätzel, M.; Infelta, P. P., On the relevance of mass transport in thin layer nanocrystalline photoelectrochemical solar cells Solar Energy Mater. Solar Cells 1996, 44, 405-438.
172. Papageorgiou, N.; Barbé, C.; Grätzel, M., Morphology and Adsorbate Dependence of Ionic Transport in Dye Sensitized Mesoporous TiO2 Films. J. Phys. Chem. B 1998, 102, 4156-4164.
173. Imtiaz A. Kathawalla, J. L. A., Pore size effects on diffusion of polystyrene in dilute solution. Ind. Eng. Chem. Res. 1988, 27, 866-871.
174. Hartmann, P.; Lee, D.-K.; Smarsly, B. M.; Janek, J., Mesoporous TiO2: Comparison of Classical Sol-Gel and Nanoparticle Based Photoelectrodes for the Water Splitting Reaction. ACS Nano 2010, 4, 3147-3154.
175. Liu, X.; Gao, Y.; Cao, C.; Luo, H.; Wang, W., Highly Crystalline Spindle-Shaped Mesoporous Anatase Titania Particles: Solution-Phase Synthesis, Characterization, and Photocatalytic properties. Langmuir 2010, 26, 7671-7674.
176. Atwater, H. A.; Polman, A., Plasmonics for improved photovoltaic devices. Nature Mater. 2010, 9, 205-213.
177. Prodan, E.; Radloff, C.; Hales, N. J.; Nordlander, P., A hybridization model for the plasmon response of complex nanostructures. Science 2003, 302, 419-422.
178. Ferry, V. E.; Munday, J. N.; Atwater, H. A., Design Considerations for Plasmonic Photovoltaics. Adv. Mater. 2010, 22, 4794-4808.
179. Testino, A.; Bellobono, I. R.; Buscaglia, V.; Canevali, C.; D'Arienzo, M.; Polizzi, S.; Scotti, R.; Morazzoni, F., Optimizing the photocatalytic properties of hydrothermal TiO2 by the control of phase composition and particle morphology. A systematic approach. J. Am. Chem. Soc. 2007, 129, 3564-3575.
180. Usseglio, S.; Damin, A.; Scarano, D.; Bordiga, S.; Zecchina, A.; Lamberti, C., (I-2)(n) encapsulation inside TiO2: A way to tune photoactivity in the visible region. J. Am. Chem. Soc. 2007, 129, 2822-2828.
181. Gur, I.; Fromer, N. A.; Geier, M. L.; Alivisatos, A. P., Air-Stable All-Inorganic Nanocrystal Solar Cells Processed from Solution. Science 2005, 310, 462-465.
182. Kongkanand, A.; Tvrdy, K.; Takechi, K.; Kuno, M.; Kamat, P. V., Quantum Dot Solar Cells. Tuning Photoresponse through Size and Shape Control of CdSe—TiO2 Architecture. J. Am. Chem. Soc. 2008, 130, 4007-4015.
183. Huynh, W. U.; Dittmer, J. J.; Alivisatos, A. P., Hybrid Nanorod Polymer Solar Cells. Science 2002, 295, 2425-2427.
184. Alexander W. Hains, Z. L., Michael A. Woodhouse and Brian A. Gregg*, Molecular Semiconductors in Organic Photovoltaic celss. Chem. Rev. 2010, 110, DOI: 10.1021/cr9002984.
185. Zhu, X.-Y.; Yang, Q.; Muntwiler, M., Charge-Transfer Excitons at Organic Semiconductor Surfaces and Interfaces. Acc. Chem. Res. 2009, 42, 1779-1787.
186. Brédas, J. L.; Norton, J. E.; Cornil, J.; Coropceanu, V., Molecular Understanding of Organic Solar Cells: The Challenges. Acc. Chem. Res. 2009, 42, 1691-1699.
187. Günes, S.; Neugebauer, H.; Sariciftci, N. S., Conjugated Polymer-Based Organic Solar Cells Chem. Rev. 2007, 107, 1324-1338.
188. Fischer, S.; Goldschmidt, J. C.; Löper, P.; Bauer, G. H.; Brüggemann, R.; Krämer, K.; Biner, D.; Hermle, M.; Glunz, S. W., Enhancement of silicon solar cell efficiency by upconversion: Optical and electrical characterization J. Appl. Phys. 2010, 108, 044912.
189. Sokolnicki, J.; Urbanski, B.; Legendziewicz, J., Investigation of Er, Er:Yb and Er:Tm systems in silica sol-gels. J. Alloys Compd 2000, 300-301, 450-455.
190. Delevaque, E.; Georges, T.; Monerie, M.; Lamouler, P.; Bayon, J. F., “Modeling of pair-induced quenching in erbium-doped silicate fibers. IEEE Photonics Technology Letters 1993, 5, 73-75
191. Boivin, D.; Föhn, T.; Burov, E.; Pastouret, A.; Cédric, G., Quenching investigation on New Erbium Doped Fibers using MCVD Nanoparticle Doping Process. Proc. of SPIE 2010, 7580, 75802B.
192. Solomon, S. D.; Bahadory, M.; Jeyarajasingam, A. V.; Rutkowsky, S. A.; Boritz, C., Synthesis and Study of Silver Nanoparticles. J. Chem. Educ. 2007, 84, 322-325.
193. Smestad, G. P.; Gratzel, M., Demonstrating Electron Transfer and Nanotechnology: A Natural Dye-Sensitized Nanocrystalline Energy Converter. J. Chem. Educ. 1998, 75, 752-756.
194. Lin, C.; Xu, T.; Yu, J.; Ge, Q.; Z., X., Hydrogen Spillover Enhanced Hydriding Kinetics of Palladium-Doped Lithium Nitride to Lithium Imide. J. Phys. Chem. C 2009, 113, 8513-8517.
195. Lin, C.; Yang, Z.; Xu, T.; Zhao, Y., An in situ electric study on primary hydrogen spillover from nanocatalysts to amorphous carbon support. Appl. Phys. Lett. 2008, 93, 233110.
196. Xu, T.; Lin, C.; Wang, C.; Brewe, D.; Y., I.; Lu, J., Synthesis of Supported Platinum Nanoparticles from Li—Pt Solid Solution. J. Am. Chem. Soc. 2010, 132, 2151-2153.
197. Zeng, X. Q.; Latimer, M. L.; Xiao, Z. L.; Panuganti, S.; Welp, U.; Kwok, W. K.; Xu, T., Hydrogen Gas Sensing with Networks of Ultrasmall Palladium Nanowires Formed on Filtration Membranes. Nano Letters 2011, 11, 262-268.
198. Cameron, P. J.; Peter, L. M. J. Phys. Chem. B 2005, 109, 7392.
199. O'Regan, B. C.; Durrant, J. R.; Sommeling, P. M.; Bakker, N. J. J. Phys. Chem. C 2007, 111, 14001.
200. Yu, H.; Zhang, S.; Zhao, H.; Xue, B.; Liu, P.; Will, G. J. Phys. Chem. C 2009, 113, 16277.
201. Kang, S. H.; Choi, S. H.; Kang, M. S.; Kim, J. Y.; Kim, H. S.; Hyeon, T.; Sung, Y. E. Adv. Mater. 2008, 20, 54.
202. Kuang, D.; Brillet, J.; Chen, P.; Takata, M.; Uchida, S.; Miura, H.; Sumioka, K.; Zakeeruddin, S. M.; Grätzel, M. ACS Nano 2008, 2, 1113.
203. Wang, Y.; Brezesinski, T.; Antonietti, M.; Smarsly, B. ACS Nano 2009, 3, 1373.
204. Wu, H.; Hu, L.; Carney, T.; Ruan, Z.; Kong, D.; Yu, Z.; Yao, Y.; Cha, J. J.; Zhu, J.; Fan, S.; Cui, Y. J. Am. Chem. Soc. 2011, 133, 27.
205. Fessenden, R. W.; Kamat, P. V. J. Phys. Chem. 1995, 99, 12902.
206. Guldin, S.; Huttner, S.; Kolle, M.; Welland, M. E.; Muller-Buschbaum, P.; Friend, R. H.; Steiner, U.; Tetreault, N. Nano Lett. 2010, 10, 2303.
207. Jacobsen, V.; Du\ddot{}rr, M.; Wendling, B.; Yasuda, A.; Nelles, G.; Knoll, W.; Kreiter, M. Appl. Surf. Sci. 2006, 252, 3903.
208. Breeze, A. J.; Schlesinger, Z.; Carter, S. A.; Brock, P. J. Phys. Rev. B 2001, 64, 125205.
209. Turrión, M.; Macht, B.; Tributsch, H.; Salvador, P. J. Phys. Chem. B 2001, 105, 9732.
210. Turrión, M.; Bisquert, J.; Salvador, P. J. Phys. Chem. B 2003, 107, 9397.
211. Kawashima, T.; Ezure, T.; Okada, K.; Matsui, H.; Goto, K.; Tanabe, N. J Photoch Photobio A 2004, 164, 199.
212. Zhi, X.; Zhao, G.; Zhu, T.; Li, Y. Surf. Interface Anal. 2008, 40, 67.
213. Kumar, V.; Govind, A.; Nagarajan, R. Inorg. Chem. 2011, 50, 5637.
214. Abel, K. A.; Boyer, J.-C.; Andrei, C. M.; van Veggel, F. C. J. M. J. Phys. Chem. Lett. 2011, 2, 185.
215. Ramasamy, E.; Lee, J. J. Phys. Chem. C 2010, 114, 22032.
216. Tiwana, P.; Docampo, P.; Johnston, M. B.; Snaith, H. J.; Herz, L. M. ACS Nano 2011, 5, 5158.
217. Chappel, S.; Chen, S.-G.; Zaban, A. Langmuir 2002, 18, 3336.
218. Prasittichai, C.; Hupp, J. T. J. Phys. Chem. Lett. 2010, 1, 1611.
219. Klein, A.; Körber, C.; Wachau, A.; Säuberlich, F.; Gassenbauer, Y.; Harvey, S. P.; Proffit, D. E.; Mason, T. O. Materials 2010, 3, 4892.
220. Avadhut, Y. S.; Weber, J.; Hammarberg, E.; Feldmann, C.; Schellenberg, I.; Pöttgen, R.; Schmedt auf der Günne, J. Chem. Mater. 2011, 23, 1526.
221. Gubbala, S.; Chakrapani, V.; Kumar, V.; Sunkara, M. K. Adv. Fund. Mater. 2008, 18, 2411.
222. Snaith, H. J.; Ducati, C. Nano Lett. 2010, 10, 1259.
223. Sellers, M. C. K.; Seebauer, E. G. J. Vac. Sci. Technol. A 2011, 29, 8, 061503.
224. Ito, S.; Nazeeruddin, M. K.; Zakeeruddin, S. M.; chy, P.; Comte, P.; Gr; tzel, M.; Mizuno, T.; Tanaka, A.; Koyanagi, T. International Journal of Photoenergy 2009, 2009.
225. Ito, S.; Zakeeruddin, S. M.; Humphry-Baker, R.; Liska, P.; Charvet, R.; Comte, P.; Nazeeruddin, M. K.; Péchy, P.; Takata, M.; Miura, H.; Uchida, S.; Grätzel, M. Adv. Mater. 2006, 18, 1202.
226. González-Pedro, V.; Xu, X.; Mora-Seró, I. n.; Bisquert, J. ACS Nano 2010, 4, 5783.
227. Wang, Q.; Ito, S.; Grätzel, M.; Fabregat-Santiago, F.; Mora-Seró, I.; Bisquert, J.; Bessho, T.; Imai, H. J. Phys. Chem. B 2006, 110, 25210.
228. Fabregat-Santiago, F.; Garcia-Belmonte, G.; Mora-Seró, I.; Bisquert, J. Phys. Chem. Chem. Phys. 2011, 13, 35.
229. Agrios, A. G.; Hagfeldt, A. J. Phys. Chem. C 2008, 112, 10021.
230. Spokoyny, A. M.; Li, T. C.; Farha, O. K.; Machan, C. W.; She, C.; Stern, C. L.; Marks, T. J.; Hupp, J. T.; Mirkin, C. A. Angew. Chem. Int. Ed. 2010, 49, 5339.
231. Wang, Q.; Zhu, K.; Neale, N. R.; Frank, A. J. Nano Lett. 2009, 9, 806.
232. Zhang, Y.; Grady, N. K.; Ayala-Orozco, C.; Halas, N. J. Nano Lett. 2011, 11, 5519.
233. Liu, L.; Karuturi, S. K.; Su, L. T.; Tok, A. I. Y. Energy Environ. Sci. 2011, 4, 209.
234. Lee, S.-H. A.; Abrams, N. M.; Hoertz, P. G.; Barber, G. D.; Halaoui, L. I.; Mallouk, T. E. J. Phys. Chem. B 2008, 112, 14415.
235. Wang, M.; Chen, P.; Humphry-Baker, R.; Zakeeruddin, S. M.; Grätzel, M. Chem Phys Chem 2009, 10, 290.
236. Ginley, D. S.; Bright, C MRS Bull. 2000, 25, 15.
237. Lewis, B. G.; Paine, D. C. MRS Bull. 2000, 25, 22.
238. Haacke, G. Annu. Rev. Mater. Sci. 1977, 7, 73.
239. Granqvist, C. G. Sol. Energy Mater. Sol. Cells 2007, 91, 1529.
240. Edwards, P. P.; Porch, A.; Jones, M. O.; Morgan, D. V.; Perks, R. M. Dalton Trans. 2004, 2995-3002.
241. Hamberg, I.; Granqvist, C. G. J. Appl. Phys. 1986, 60, R123-R159.
242. Hoel, C. A.; Mason, T. O.; Gaillard, J.-F.; Poeppelmeier, K. R. Chem. Mater. 2010, 22, 2569-3579.
243. Rauf, I. A. Mater. Lett. 1993, 18, 123-127.
244. Armstrong, N. R.; Veneman, P. A.; Ratcliff, E.; Placencia, D.; Brumbach, M. Acc. Chem. Res. 2009, 42, 1748-1757.
245. Walzer, K.; Maennig, B.; Pfeiffer, M.; Leo, K. Chem. Rev. 2007, 107, 1233.
246. Rühle, S.; Cahen, D. J. Phys. Chem. B 2004, 108, 17946-17951.
247. Brédas, J. L.; Norton, J. E.; Cornil, J.; Coropceanu, V. Acc. Chem. Res. 2009, 42, 1691-1699.
248. Jin, W.-M.; Shin, J.-H.; Cho, C.-Y.; Kang, J.-H.; Park, J. H.; Moon, J. H. ACS Appl. Mater. Interfaces 2010, 2, 2970-2973.
249. Taranekar, P.; Qiao, Q.; Jiang, H.; Ghiviriga, I.; Schanze, K. S.; Reynolds, J. R. J. Am. Chem. Soc. 2007, 129, 8958-8959.
250. Li, Y. Z.; Kunitake, T.; Fujikawa, S. J. Phys. Chem. B 2006, 110, 13000-13004.
251. Xie, H.; Li, Y.; Jin, S.; Han, J.; Zhao, X. J. Phys. Chem. C 2010, 114, 9706-9712.
252. Fujihara, S.; Maeda, T.; Ohgi, H.; Hosono, E.; Imai, H.; Kim, S.-H. Langmuir 2004, 20, 6476-6481.
253. Martinez, A. I.; Huerta, L.; de Leon, J. M. O. R.; Acosta, D.; Malik, O.; Aguilar, M. J. Phys. D: Appl. Phys. 2006, 39, 5091-5096.
254. Ramaiah, K. S.; Raja, V. S. Appl. Surf. Sci. 2006, 253, 1451-1458.
255. Smith, A.; Laurent, J. M.; Smith, D. S.; Bonnet, J. P.; Clemente, R. R. Thin Solid Films 1995, 266, 20-30.
256. Li, H.; Jiang, B.; Schaller, R.; Wu, J.; Jiao, J. J. Phys. Chem. C 2010, 114, 11375-11380.
257. Jeong, J-A and Kim, H-K, Solar energy Materials & Solar Cells, 2011, 95, 344-348)
258. Patent Application Publication, Pub. No. US 2011/0220192.
259. Sugihara et al., U.S. Pat. No. 6,278,056.
260. Moyo et al. Sensors, 2012, 12, 923-953.
261. Patent Application Publication, Pub. No. US 2009/0202880.

1. A photovoltaic device, comprising:
(1) a transparent first conductive layer,
(2) a semiconductor layer, on and in contact with the first conductive layer,
(3) an electrolyte or p-type semiconductor, on the semiconductor layer, and
(4) a second conductive layer, on the electrolyte or p-type semiconductor,
wherein the semiconductor layer has a thickness of at most 100 nm,
the first conductive layer has a surface roughness factor (SRF) of at least 10, and
the semiconductor layer has a surface roughness factor (SRF) of at least 10.

2. The photovoltaic device of claim 1, further comprising (5) a chromophore, on the semiconductor layer.

3. The photovoltaic device of claim 1, wherein the semiconductor layer has a thickness of at most 30 nm.

4. The photovoltaic device of claim 1, wherein the semiconductor layer has a thickness of at most 20 nm.

5. The photovoltaic device of claim 1, wherein the semiconductor layer has a thickness of at most 10 nm.

6. The photovoltaic device of claim 1, wherein the first conductive layer has a SRF of at least 100.

7. The photovoltaic device of claim 1, wherein the semiconductor layer has a SRF of at least 100.

8. The photovoltaic device of claim 1, wherein the first conductive layer has a SRF of at least 400.

9. The photovoltaic device of claim 1, wherein the semiconductor layer has a SRF of at least 400.

10. The photovoltaic device of claim 1, further comprising (6) a blocking layer, on the semiconductor layer.

11. The photovoltaic device of claim 10, wherein the blocking layer comprises at least one member selected from the group consisting of magnesium oxide, aluminum oxide, zirconium oxide, boron nitride, silicon oxide, diamond and barium titanate.

12. The photovoltaic device of claim 10, wherein the blocking layer has a thickness of at most 2 nm.

13. The photovoltaic device of claim 10, wherein the blocking layer has a thickness of less than one atomic layer.

14. The photovoltaic device of claim 2, wherein the chromophore is a pigment.

15. The photovoltaic device of claim 2, wherein the chromophore is a non-platinum group metal containing dye.

16. The photovoltaic device of claim 2, wherein the chromophore is a metal free dye.

17. The photovoltaic device of claim 2, wherein the chromophore is a pigment or metal free dye.

18. The photovoltaic device of claim 1, comprising the electrolyte, and wherein the electrolyte does not comprises I⁻ nor I₃⁻.

19. The photovoltaic device of claim 1, comprising the electrolyte, and wherein the electrolyte comprises a redox mediator containing iron.

20. The photovoltaic device of claim 19, wherein the redox mediator is ferrocene.

21-31. (canceled)
